(19) United States
(12) Patent Application Publication
(10) Pub. No.: US 2026/0156894 A1
(43) Pub. Date: Jun. 4, 2026

(54) SEMICONDUCTOR STRUCTURE AND METHOD FOR FORMING THE SAME

(71) Applicant: Taiwan Semiconductor Manufacturing Company, Ltd., Hsinchu (TW)

(72) Inventors: Che-Chi SHIH, Taoyuan City (TW); Kuan-Kan HU, Hsinchu (TW); Yu-Hsien CHIANG, Hsinchu City (TW); Zhi-Chang LIN, Zhubei City (TW); Ku-Feng Yang, Baoshan Township (TW); Szuya Liao, Zhubei Hsinchu (TW)

(21) Appl. No.: 18/964,337

(22) Filed: Nov. 29, 2024

(51) Int. Cl. H10D 64/01; H10D 30/01; H10D 30/43; H10D 30/67; H10D 62/10; H10D 64/27; H10D 84/01; H10D 84/03; H10D 84/85

(52) U.S. Cl. CPC H10D 64/017; H10D 30/014; H10D 30/43; H10D 30/6735; H10D 30/6757; H10D 62/121; H10D 64/513; H10D 84/017; H10D 84/0186; H10D 84/038; H10D 84/851

(57) ABSTRACT

A method of forming a semiconductor structure, including forming a first epitaxial structure and a first bonding layer thereon, forming a second epitaxial structure and a second bonding layer thereon, bonding the first and second epitaxial structures to form a third epitaxial structure by bonding the first and second bonding layers, and patterning the third epitaxial structure to form a fin structure. The method further includes forming a dummy gate over the fin structure, and etching the fin structure to form source/drain trenches on opposite sides of the dummy gate. The method further includes forming a first gate trench exposing a dummy gate dielectric layer of the dummy gate, performing an etching process to remove the dummy gate dielectric layer of the dummy gate and a topmost semiconductor layer of the fin structure through the first gate trench, and forming a gate structure in the first gate trench.

### BACKGROUND

The semiconductor integrated circuit (IC) industry has experienced exponential growth. Technological advances in IC materials and design have produced generations of ICs where each generation has smaller and more complex circuits than the previous generation. In the course of IC evolution, functional density (i.e., the number of interconnected devices per chip area) has generally increased while geometric size (i.e., the smallest component (or line) that can be created using a fabrication process) has decreased. This scaling down process generally provides benefits by increasing production efficiency and lowering associated costs. Such scaling down has also increased the complexity of processing and manufacturing ICs and, for these advancements to be realized, similar developments in IC processing and manufacturing are needed.

As IC technologies progress towards smaller technology nodes, the gate-all-around (GAA) devices have been introduced to improve gate control by increasing gate-channel coupling, reducing off-state current, and reducing short-channel effects (SCEs). As GAA devices continue to be developed, complementary metal-oxide-semiconductor field effect transistors (CMOSFET or CFET) has been provided due to their high noise immunity and low static power consumption. However, although existing technologies for fabricating CFETs have been generally adequate for their intended purposes, they have not been entirely satisfactory in all respects.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1A is an X-Z cross-sectional view of a semiconductor structure, in accordance with some embodiments of the present disclosure.

FIG. 1B is a Y-Z cross-sectional view of the semiconductor structure, in accordance with some embodiments of the present disclosure.

FIG. 1C is a Y-Z cross-sectional view of the semiconductor structure, in accordance with some embodiments of the present disclosure.

FIG. 1D is an X-Z cross-sectional view of a semiconductor structure, in accordance with some embodiments of the present disclosure.

FIG. 1E is a Y-Z cross-sectional view of the semiconductor structure, in accordance with some embodiments of the present disclosure.

FIG. 1F is a Y-Z cross-sectional view of the semiconductor structure, in accordance with some embodiments of the present disclosure.

FIG. 2 is an X-Z cross-sectional view of a semiconductor structure, in accordance with some alternative embodiments of the present disclosure.

FIGS. 3A, 3B, 4, 5, 6A, 6B, 7A, and 7B are perspective views of a workpiece at various fabrication stages, in accordance with some embodiments of the present disclosure.

FIGS. 8A, 9A, 10A, 11A, 12A, 13A, 14A, 15A, 16A, 17A, and 18A are X-Z cross-sectional views of the workpiece at various fabrication stages along line A-A′ of FIG. 7A, in accordance with some embodiments of the present disclosure.

FIGS. 8B, 9B, 10B, 11B, 12B, 13B, 14B, 15B, 16B, 17B, and 18B are Y-Z cross-sectional views of the workpiece at various fabrication stages along line B-B′ of FIG. 7A, in accordance with some embodiments of the present disclosure.

FIGS. 8C, 15C, 16C, 17C, and 18C are Y-Z cross-sectional views of the workpiece at various fabrication stages along line C-C′ of FIG. 7A, in accordance with some embodiments of the present disclosure.

FIGS. 8D, 9C, 10C, 11C, 12C, 13C, 14C, 15D, 16D, 17D and 18D are X-Z cross-sectional views of the workpiece at various fabrication stages along line D-D′ of FIG. 7B, in accordance with some embodiments of the present disclosure.

FIGS. 8E, 9D, 10D, 11D, 12D, 13D, 14D, 15E, 16E, 17E and 18E are Y-Z cross-sectional views of the workpiece at various fabrication stages along line E-E′ of FIG. 7B, in accordance with some embodiments of the present disclosure.

FIGS. 8F, 15F, 16F, 17F, and 18F are Y-Z cross-sectional views of the workpiece at various fabrication stages along line F-F′ of FIG. 7B, in accordance with some embodiments of the present disclosure.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

The present disclosure is generally related to semiconductor devices, and more particularly to field-effect transistors (FETs), such as three-dimensional complementary field effect transistors (CFETs) with gate-all-around (GAA) structures. Generally, a CFET may include an n-type FET (NFET) and a p-type FET (PFET) disposed vertically with a plurality of vertically stacked nanostructures (e.g., nanosheets, nanowires, or nanorods) in a channel region of the CFET, thereby allowing better gate control, lowered leakage current, and improved scaling capability for various IC applications.

The GAA structures may be patterned by any suitable method. For example, the GAA structures may be patterned using one or more photolithography processes, including double-patterning or multi-patterning processes. Generally speaking, double-patterning or multi-patterning processes combine photolithography and self-aligned processes, allowing patterns to be created that have, for example, pitches smaller than what is otherwise obtainable using a single, direct photolithography process. For example, in some embodiments, a sacrificial layer is formed over a substrate and is patterned using a photolithography process. Spacers are formed alongside the patterned sacrificial layer using a self-aligned process. The sacrificial layer is then removed, and the remaining spacers may then be used to pattern the GAA structure.

In the existing process for manufacturing CFET device, the number of channels (i.e., nanostructures) has been defined when the initial epitaxial structure is grown on the wafer, and thus the number of channels cannot be changed. However, depending on design requirements, different CFET devices on the same wafer may require different performance, which means a different number of channels. Therefore, a novel structure and fabricating method are needed to provide the flexibility for modifying the number of channels of CFET device after the initial epitaxial structure has been grown, thereby modifying the device performance during the fabrication process.

Embodiments of the present disclosure offer advantages over the existing art, though it is understood that other embodiments may offer different advantages, not all advantages are necessarily discussed herein, and no particular advantage is required for all embodiments. For example, embodiments discussed herein include structures and methods that include forming two initial epitaxial structures and bonding the two initial epitaxial structures together. Generally, a sacrificial layer (e.g. silicon germanium (SiGe) layers with high Ge concentration) may be formed first and may be replaced afterwards by a dielectric material as a middle insulator between two transistors of a CFET device. However, in the embodiments of the present disclosure, the bonding layers of the initial epitaxial structures may function as a middle insulator after bonding, and thus the process for forming the middle insulator can be omitted. In addition, since the silicon germanium (SiGe) with high Ge concentration in a single epitaxial structure has a limitation of critical thickness, the SiGe layer with high Ge concentration cannot be grown too thick. Therefore, by bonding two initial epitaxial structures as described above, the bonding layers can replace the sacrificial layer with high Ge concentration for forming middle insulator, thereby releasing budget of critical thickness. Meanwhile, the released budget can be used to form an additional SiGe layer with high Ge concentration in one of the initial epitaxial structures. The additional SiGe layer with high Ge concentration can be replaced by a dielectric layer during the subsequent process, and the dielectric layer can function as an etch stop layer during the process for reducing the number of channels. With the assistance of the etch stop layer, the number of channels of CFET device can be modified during the fabrication process. As a result, the flexibility for modifying the number of channels to modify the device performance is provided.

The various aspects of the present disclosure will now be described in more detail with reference to the figures. For avoidance of doubts, the X-direction, the Y-direction, and the Z-direction in the figures are perpendicular to one another and are used consistently. Throughout the present disclosure, like reference numerals denote like features unless otherwise indicated.

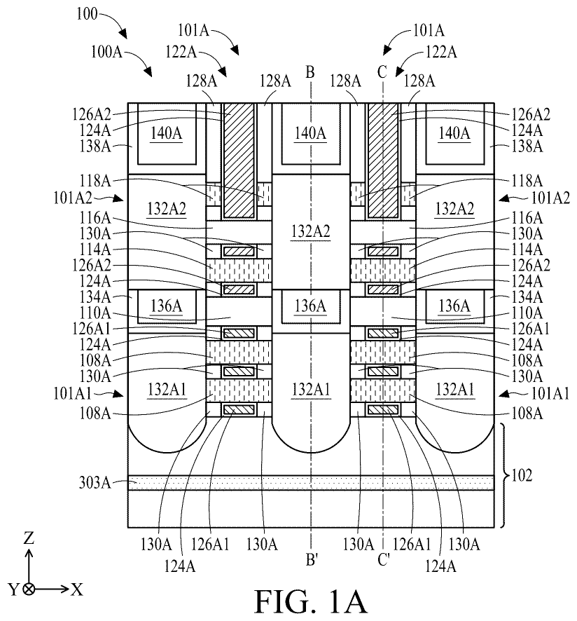

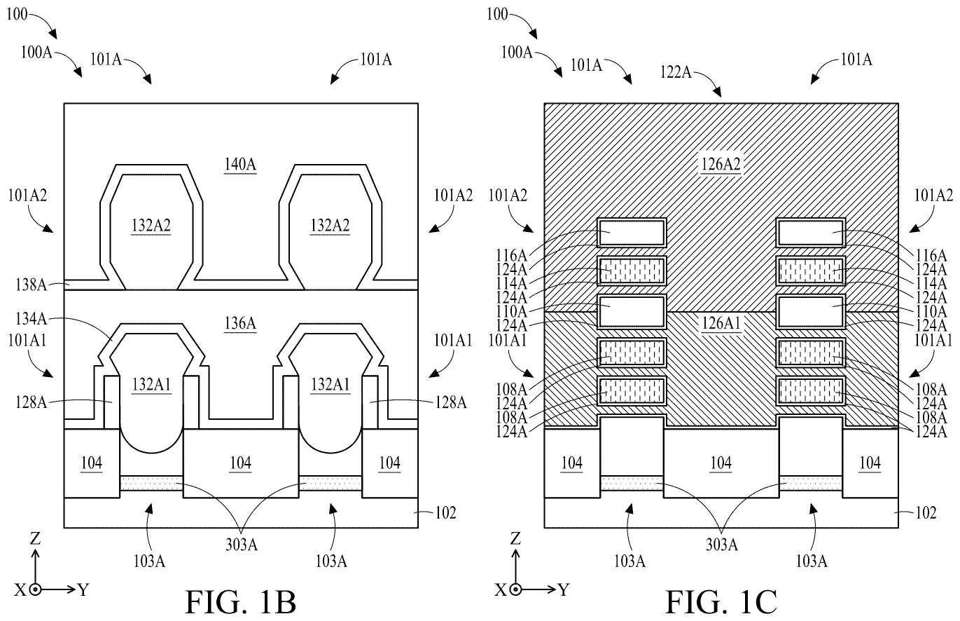

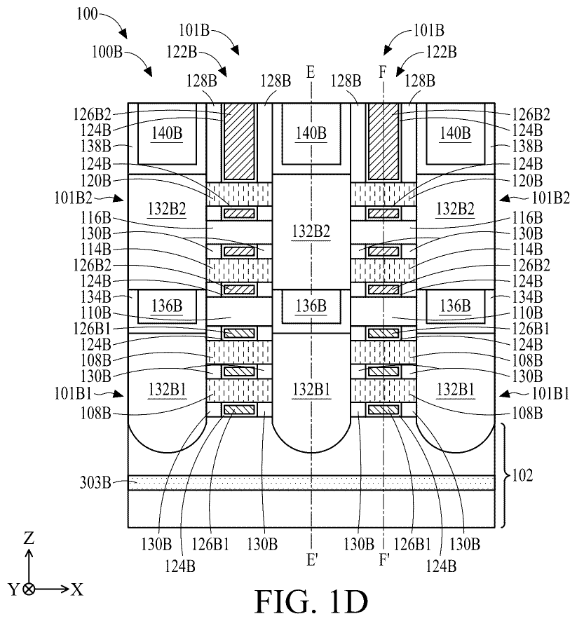

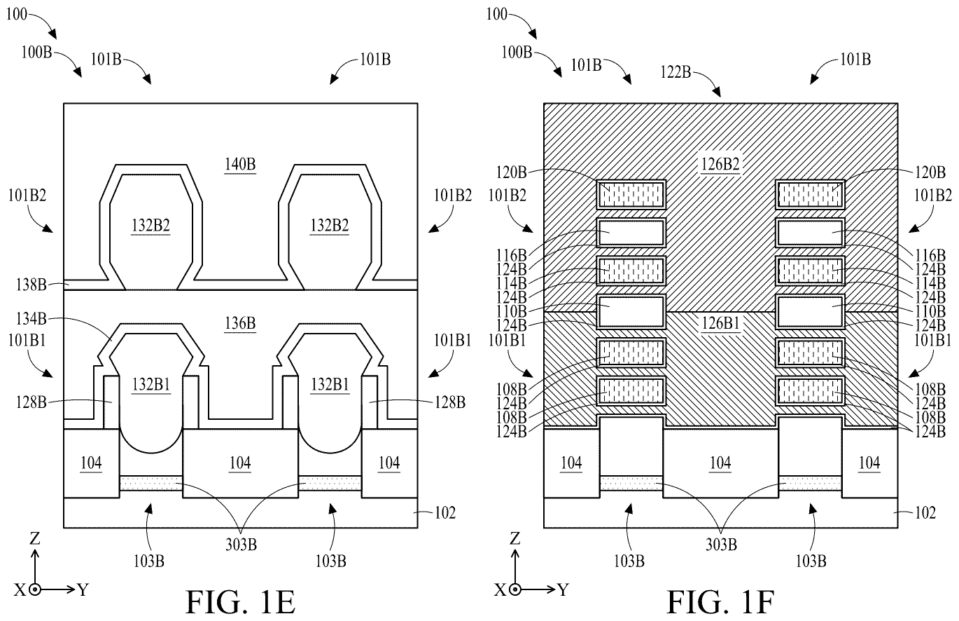

FIGS. 1A-1F illustrate cross-sectional views of a semiconductor structure 100, in accordance with some embodiments of the present disclosure. FIG. 1A is an X-Z cross-sectional view of a semiconductor structure 100A of the semiconductor structure 100, in accordance with some embodiments. FIG. 1B and FIG. 1C are Y-Z cross-sectional views of the semiconductor structure 100A along line B-B′ and line C-C′ of FIG. 1A, respectively, in accordance with some embodiments. FIG. 1D is an X-Z cross-sectional view of a semiconductor structure 100B of the semiconductor structure 100, in accordance with some embodiments. FIG. 1E and FIG. 1F are Y-Z cross-sectional views of the semiconductor structure 100B along line E-E′ and line F-F′ of FIG. 1D, respectively, in accordance with some embodiments.

Referring to FIGS. 1A-1F, the semiconductor structure 100 may include the semiconductor structure 100A (shown in FIGS. 1A-1C) and the semiconductor structure 100B (shown in FIGS. 1D-1F). In some embodiments, the semiconductor structure 100A includes complementary field effect transistors (CFETs) 101A that are arranged in the X-direction and the Y-direction, and the semiconductor structure 100B includes CFETs 101B that are arranged in the X-direction and the Y-direction. Each of the CFETs 101A has a lower device 101A1 and an upper device 101A2 disposed over (or vertically overlaps) the lower device 101A1 in the Z-direction, as shown in FIGS. 1A-1C. Each of the CFETs 101B has a lower device 101B1 and an upper device 101B2 disposed over (or vertically overlaps) the lower device 101B1 in the Z-direction, as shown in FIGS. 1D-1F. In some embodiments, the lower devices 101A1 and 101B1 may be p-type field effect transistors (PFETs), and the upper devices 101A2 and 101B2 may be n-type field effect transistors (NFETs). In other embodiments, the lower devices 101A1 and 101B1 may be NFETs and the upper device 101A2 and 101B2 may be PFETs.

The semiconductor structure 100 further includes a substrate 102. For example, in the semiconductor structure 100A, the substrate 102 includes base portions 103A that are protruded from the substrate 102 under the nanostructures (e.g., nanostructures 108A and 114A described below). For example, in the semiconductor structure 100B, the substrate 102 includes base portions 103B that are protruded from the substrate 102 under the nanostructures (e.g., nanostructures 108B, 114B, and 120B described below). Subsequent features for the CFETs 101A and 101B are formed over the base portions 103A and 103B of the substrate 102, as described in further detail below. In some embodiments, after the resultant lower devices 101A1, 101B1 and upper devices 101A2, 101B2 of the CFETs 101A and 101B are formed, the substrate 102 may be thinned (or partially removed) by a suitable process (e.g., a chemical mechanical polishing (CMP) process) for forming backside interconnection.

In some embodiments, the semiconductor structure 100 further includes isolation structures 104 in and/or over the substrate 102. The isolation structures 104 may be formed between the base portions 103A/103B of the substrate 102. In some embodiments, top surfaces of the isolation structures 104 are lower than top surfaces of the substrate 102 (more specifically, top surfaces of the base portions 103A and 103B).

In some embodiments, as shown in FIGS. 1A-1C, the semiconductor structure 100A may include two groups of nanostructures, such as a group of nanostructures 108A and a group of nanostructures 114A. In some embodiments, as shown in FIGS. 1D-1F, the semiconductor structure 100B includes two groups of nanostructures, such as a group of nanostructures 108B and a group of nanostructures 114B and 120B. The nanostructures 108A, 108B, 114A, 114B, and 120B may also be referred to as channels, channel layers, nanosheets, or nanowires. In some embodiments, the nanostructure 114A are disposed over (or vertically overlap) the nanostructures 108A in Z-direction, and the nanostructures 114B and 120B are disposed over (or vertically overlap) the nanostructures 108B in Z-direction.

The nanostructures 108A are used for the lower devices 101A1 in the CFETs 101A, and the nanostructure 114A is used for the upper devices 101A2 in the CFETs 101A. The nanostructures 108B are used for the lower devices 101B1 in the CFETs 101B, and the nanostructures 114B and 120B are used for the upper devices 101B2 in the CFETs 101B. Furthermore, the nanostructures 108A and 114A are suspended over the base portions 103A, and the nanostructures 108B, 114B, 120B are suspended over the base portions 103B.

In some embodiments, the semiconductor structure 100A further includes middle insulators 110A, and each of the middle insulators 110A is disposed between the topmost nanostructure 108A and the nanostructure 114A. In some embodiments, the group of nanostructures 108A is separated from the nanostructures 114A by the middle insulators 110A. In some embodiments, the semiconductor structure 100A further includes etch stop layers (ESLs) 116A that are disposed over the nanostructures 114A. In some embodiments, the nanostructures 108A, the middle insulators 110A, the nanostructures 114A, and the ESLs 116A are extended in the X-direction and vertically stacked (or arranged) in the Z-direction. In the Z-direction, the nanostructures 108A may be spaced apart from each other, the topmost nanostructures 108A and the nanostructures 114A may be spaced apart from the middle insulators 110A, and the middle insulators 110A and the ESLs 116A may be spaced apart from the nanostructure 114A.

In some embodiments, the semiconductor structure 100B further includes middle insulators 110B, and each of the middle insulator 110B is disposed between the topmost nanostructure 108B and the nanostructure 114B. In some embodiments, the group of nanostructures 108B is separated from the group of nanostructures 114B and 120B by the middle insulators 110B. In some embodiments, the semiconductor structure 100B further includes ESLs 116B that are disposed over the nanostructures 114B and between the nanostructures 114B and 120B. In some embodiments, the nanostructures 108B, the middle insulators 110B, the nanostructures 114B, the ESLs 116B, and the nanostructures 120B are extended in the X-direction and vertically stacked (or arranged) in the Z-direction. In the Z-direction, the nanostructures 108B may be spaced apart from each other, the topmost nanostructures 108B and the nanostructures 114B may be spaced apart from the middle insulators 110B, the middle insulators 110B and the ESLs 116B may be spaced apart from the nanostructure 114B, and the nanostructures 114B and 120B may be spaced apart from the ESLs 116B.

In some embodiments, one or two nanostructures are vertically stacked (or arranged) from each other in the Z-direction for one transistor. For example, in single CFET 101A, the lower device 101A1 has two nanostructures 108A vertically stacked from each other in the Z-direction, and the upper device 101A2 has one nanostructures 114A vertically stacked over the nanostructures 108A, as shown in FIGS. 1A-1C. For example, in single CFET 101B, the lower device 101B1 has two nanostructures 108B vertically stacked from each other in the Z-direction, and the upper device 101B2 has two nanostructures (i.e., nanostructures 114B and 120B) vertically stacked from each other in the Z-direction, as shown in FIGS. 1D-1F. However, there may be another appropriate number of nanostructures in one transistor. For example, there may be 1, 2, 3, 4, or more than 4 nanostructures in one transistor.

In some embodiments, the semiconductor structure 100A further includes gate structures 122A wrapped around the nanostructures, as shown in FIGS. 1A-1C. In single CFET 101A, the gate structure 122A may be wrapped around the nanostructures 108A in the lower device 101A1, and wrapped around the nanostructure 114A and the ESL 116A in the upper device 101A2. The CFETs 101A disposed along the Y-direction may share the same gate structure 122A that extends in the Y-direction. In some embodiments, the semiconductor structure 100B further includes gate structures 122B wrapped around the nanostructures, as shown in FIGS. 1D-1F. In single CFET 101B, the gate structure 122B may be wrapped around the nanostructures 108B in the lower device 101B1, and wrapped around the nanostructure 114B and 120B and the ESL 116B in the upper device 101B2. The CFETs 101B disposed along the Y-direction may share the same gate structure 122B that extends in the Y-direction.

The gate structure 122A includes a gate dielectric layer 124A, a gate electrode layer 126A1, and a gate electrode layer 126A2. In some embodiments, the gate dielectric layer 124A wraps around each of the nanostructures 108A and 114A, the middle insulator 110A, and the ESL 116A, as shown in FIGS. 1A-1C. The gate electrode layer 126A1 may be wrapped around the portions of the gate dielectric layer 124A that are wrapped around the nanostructures 108A, so as to form a first gate structure used for the lower device 101A1 of the CFET 101A. The gate electrode layer 126A2 may be wrapped around the portions of the gate dielectric layer 124A that are wrapped around the nanostructures 114A and the ESL 116A, so as to form a second gate structure used for the upper device 101A2 of the CFET 101A. The gate structure 122A may be constituted by the first gate structure and the second gate structure.

The gate structure 122B includes a gate dielectric layer 124B, a gate electrode layer 126B1, and a gate electrode layer 126B2. In some embodiments, the gate dielectric layer 124B wraps around each of the nanostructures 108B, 114B, and 120B, the middle insulator 110B, and the ESL 116B, as shown in FIGS. 1D-1F. The gate electrode layer 126B1 may be wrapped around the portions of the gate dielectric layer 124B that are wrapped around the nanostructures 108B, so as to form a first gate structure used for the lower device 101B1 of the CFET 101B. The gate electrode layer 126B2 may be wrapped around the portions of the gate dielectric layer 124B that are wrapped around the nanostructures 114B and 1120B and the ESL 116B, so as to form a second gate structure used for the upper device 101B2 of the CFET 101B. The gate structure 122B may be constituted by the first gate structure and the second gate structure.

In some embodiments, the gate dielectric layers 124A and 124B are also formed on the top surfaces of the isolation structures 104 and on the top surfaces and sidewalls of the substrate 102 (e.g., the top surfaces and sidewalls of the base portions 103A and 103B). In some embodiments, the gate dielectric layer 124A is further be formed on the sidewalls of gate spacers 128A and inner spacers 130A (discussed below), and the gate dielectric layer 124B is further be formed on the sidewalls of gate spacers 128B and inner spacers 130B (discussed below), as shown in FIGS. 1A-1F. In some embodiments, the top surface of the gate electrode layer 126A1 is lower than the top surface of the middle insulator 110A, and the bottom surface of the gate electrode layer 126A2 is higher than the bottom surface of the middle insulator 110A, as shown in FIG. 1C. In some embodiments, the top surface of the gate electrode layer 126B1 is lower than the top surface of the middle insulator 110B, and the bottom surface of the gate electrode layer 126B2 is higher than the bottom surface of the middle insulator 110B, as shown in FIG. 1F. In some embodiments, the gate structures 122A and 122B further includes interfacial layers (not shown) formed between the gate dielectric layers 124A and the nanostructures (e.g., nanostructures 108A and 114A) or between the gate dielectric layers 124B and the nanostructures (e.g., nanostructures 108B, 114B, and 120B).

In some embodiments, the semiconductor structure 100A further includes gate spacers 128A formed on opposite sides of the gate structures 122A. Specifically, the gate spacers 128A are formed on the sidewalls of the gate structures 122A and over the nanostructures, as shown in FIG. 1A. Furthermore, the gate spacers 128A may extend lengthwise in the Y-direction (e.g., parallel to the gate structures 122A), and are formed on opposite sidewalls of the gate structures 122A in the X-direction. The gate spacers 128A are located over the topmost nanostructures and on the top sidewalls of the gate structures 122A, and thus are also referred to as gate top spacers or top spacers.

In some embodiments, the semiconductor structure 100B further includes gate spacers 128B formed on opposite sides of the gate structures 122B. Specifically, the gate spacers 128B are formed on the sidewalls of the gate structures 122B and over the nanostructures, as shown in FIG. 1D. Furthermore, the gate spacers 128B may extend lengthwise in the Y-direction (e.g., parallel to the gate structures 122B), and are formed on opposite sidewalls of the gate structures 122B in the X-direction. The gate spacers 128B are located over the topmost nanostructures (e.g., the nanostructures 120B) and on the top sidewalls of the gate structures 122B, and thus are also referred to as gate top spacers or top spacers.

In some embodiments, the semiconductor structure 100A further includes inner spacers 130A formed on opposite sides of the gate structures 122A. More specifically, the inner spacers 130A are formed on the sidewalls of the gate structure 122A, and below the gate spacers 128A. In some embodiments, the inner spacers 130A are also formed vertically between the bottommost nanostructures 108A and the substrate 102, between the adjacent nanostructures 108A, between the topmost nanostructures 108A and the middle insulators 110A, between the middle insulators 110A and the nanostructures 114A, between the nanostructures 114A and the ESLs 116A, and over the ESLs 116A, as shown in FIG. 1A. In some embodiments, the inner spacers 130A are laterally between the source/drain features 132A1/132A2 (described below) and the gate structures 122A in the X-direction.

In some embodiments, the semiconductor structure 100B further includes inner spacers 130B formed on opposite sides of the gate structures 122B. More specifically, the inner spacers 130B are formed on the sidewalls of the gate structure 122B, and below the gate spacers 128B and the topmost nanostructures (e.g., the nanostructures 120B). In some embodiments, the inner spacers 130B are also formed vertically between the bottommost nanostructures 108B and the substrate 102, between the adjacent nanostructures 108B, between the topmost nanostructures 108B and the middle insulators 110B, between the middle insulators 110B and the nanostructures 114B, between the nanostructures 114B and the ESLs 116B, and between the ESLs 116B and the nanostructures 120B, as shown in FIG. 1D. In some embodiments, the inner spacers 130B are laterally between the source/drain features 132B1/132B2 (described below) and the gate structures 122B in the X-direction.

In some embodiments, the semiconductor structure 100A may further include semiconductor segments 118A, as shown in FIG. 1A. In some embodiments, the semiconductor segments 118A are formed on opposite sides of the gate structures 122A in the X-direction. In some embodiments, in the Z-direction, the semiconductor segments 118A are formed below the gate spacers 128A and above the ESLs 116A, so that the semiconductor segments 118A are between the gate spacers 128A and the ESLs 116A. In further embodiments, the semiconductor segments 118A are formed between the gate spacers 128A and the inner spacers 130A that are formed over the ESLs 116A. In some embodiments, the gate dielectric layers 124A are also formed on semiconductor segments 118A, and the semiconductor segments 118A are laterally between the source/drain features 132A1/132A2 (described below) and the gate structures 122A in the X-direction.

In some embodiments, each of the CFETs 101A includes source/drain features 132A1 and 132A2 over the substrate 102, as shown in FIGS. 1A-1C. Specifically, the source/drain features 132A1 are disposed over the substrate 102, and the source/drain features 132A2 are disposed over (or vertically overlap) the source/drain features 132A1. In some embodiments, the source/drain features 132A2 are vertically separated from the source/drain features 132A1 in the Z-direction. In some embodiments, the source/drain features 132A1 are disposed on opposite sides of the gate structures 122A (e.g., the gate electrode layers 126A1) in the X-direction to form lower devices 101A1, as shown in FIG. 1A. Similarly, the source/drain features 132A2 are disposed on opposite sides of the gate structure 122A (e.g., the gate electrode layers 126A2) in the X-direction to form the upper devices 101A2, as shown in FIG. 1A.

The nanostructures 108A extend in the X-direction to connect one source/drain feature 132A1 to another source/drain feature 132A1, and the nanostructures 114A extend in the X-direction to connect one source/drain feature 132A2 to another source/drain feature 132A2, in accordance with some embodiments. More specifically, the source/drain features 132A1 are disposed on opposite sides of the nanostructures 108A in the X-direction, and the source/drain features 132A2 are disposed on opposite sides of the nanostructures 114A and the ESLs 116A in the X-direction. Therefore, in the X-direction, the source/drain features 132A1 are attached and electrically connected to the nanostructures 108A, and the source/drain features 132A2 are attached and electrically connected to the nanostructures 114A. The semiconductor segments 118A and the ESLs 116A are also attached to the source/drain features 132A2 in the X-direction.

In some embodiments, each of the CFETs 101B includes source/drain features 132B1 and 132B2 over the substrate 102, as shown in FIGS. 1D-1F. Specifically, the source/drain features 132B1 are disposed over the substrate 102, and the source/drain features 132B2 are disposed over (or vertically overlap) the source/drain features 132B1. In some embodiments, the source/drain features 132B2 are vertically separated from the source/drain features 132B1 in the Z-direction. In some embodiments, the source/drain features 132B1 are disposed on opposite sides of the gate structures 122B (e.g., the gate electrode layers 126B1) in the X-direction to form lower devices 101B1, as shown in FIG. 1D. Similarly, the source/drain features 132B2 are disposed on opposite sides of the gate structure 122B (e.g., the gate electrode layers 126B2) in the X-direction to form the upper devices 101B2, as shown in FIG. 1D.

The nanostructures 108B extend in the X-direction to connect one source/drain feature 132B1 to another source/drain feature 132B1, and the nanostructures 114B and 120B extend in the X-direction to connect one source/drain feature 132B2 to another source/drain feature 132B2, in accordance with some embodiments. More specifically, the source/drain features 132B1 are disposed on opposite sides of the nanostructures 108B in the X-direction, and the source/drain features 132B2 are disposed on opposite sides of the nanostructures 114B and 120B and the ESLs 116B in the X-direction. Therefore, in the X-direction, the source/drain features 132B1 are attached and electrically connected to the nanostructures 108B, and the source/drain features 132B2 are attached and electrically connected to the nanostructures 114B and 120B. The ESLs 116B are also attached to the source/drain features 132B2 in the X-direction.

The source/drain features 132A1, 132A2, 132B1, and 132B2 may also be referred to as source/drain, or source/drain regions. In some embodiments, source/drain feature(s) may refer to a source or a drain, individually or collectively dependent upon the context.

In some embodiments, the semiconductor structures 100A and 100B further include undoped epitaxial layers (not shown) formed under the source/drain features 132A1 and 132B1 and over the substrate 102 in the Z-direction. In some embodiments, the undoped epitaxial layers are formed vertically between and in direct contact with the source/drain features 132A1/132B1 and the substrate 102 in the Z-direction. In some embodiments, the semiconductor structures 100A and 100B may further include bottom isolation layers (not shown) under the source/drain features 132A1 and 132B1 and over the undoped epitaxial layers or the substrate 102 in the Z-direction. In further embodiments, the bottom isolation layers are formed vertically between and in contact with the source/drain features 132A1/132B1 and the undoped epitaxial layers, or vertically between and in contact with the source/drain features 132A1/132B1 and the substrate 102.

In some embodiments, the semiconductor structure 100A may further include contact etch stop layers (CESLs) 134A and interlayer dielectric (ILD) layers 136A that are formed between the source/drain features 132A1 and 132A2 in the Z-direction. In some embodiments, the CESLs 134A are conformally formed on the source/drain features 132A1, and the ILD layers 136A are formed on the CESLs 134A. In further embodiments, the CESLs 134A are also conformally formed on portions of the gate spacers 128A that are formed on opposite sides of the source/drain features 132A1 in the X-direction, as shown in FIG. 1B. In some embodiments, both the CESLs 134A and the ILD layers 136A are in contact with the source/drain features 132A2. In some embodiments, the CESLs 134A are also in contact with the middle insulators 110A, and in partial contact with the inner spacers 130A that are in direct contact with the middle insulators 110A, as shown in FIG. 1A.

In some embodiments, the semiconductor structure 100B may further include CESLs 134B and ILD layers 136B that are formed between the source/drain features 132B1 and 132B2 in the Z-direction. In some embodiments, the CESLs 134B are conformally formed on the source/drain features 132B1, and the ILD layers 136B are formed on the CESLs 134B. In further embodiments, the CESLs 134B are also conformally formed on portions of the gate spacers 128B that are formed on opposite sides of the source/drain features 132B1 in the X-direction, as shown in FIG. 1E. In some embodiments, both the CESLs 134B and the ILD layers 136B are in contact with the source/drain features 132B2. In some embodiments, the CESLs 134B are also in contact with the middle insulators 110B, and in partial contact with the inner spacers 130B that are in direct contact with the middle insulators 110B, as shown in FIG. 1D.

In some embodiments, the semiconductor structure 100A may further include CESLs 138A and ILD layers 140A on the CESLs 138A. In some embodiments, the CESLs 138A are formed over the source/drain features 132A2, the CESLs 134A, and the ILD layers 136A. More specifically, the CESLs 138A may be conformally formed on the sidewalls of the gate spacers 128A, on the top surfaces of the ILD layers 136A, and on the top surfaces and the sidewalls of the source/drain features 132A2, as shown in FIGS. 1A-1C. In some embodiments, the ILD layers 140A are formed on the CESLs 138A to fill the spaces in the CESLs 138A and between the gate spacers 128A, as shown in FIGS. 1A-1C. In some embodiments, the source/drain features 132A1 and 132A2 are spaced apart from each other by the CESLs 138A and the ILD layers 140A.

In some embodiments, the semiconductor structure 100B may further include CESLs 138B and ILD layers 140B on the CESLs 138B. In some embodiments, the CESLs 138B are formed over the source/drain features 132B2, the CESLs 134B, and the ILD layers 136B. More specifically, the CESLs 138B may be conformally formed on the sidewalls of the gate spacers 128B, on the top surfaces of the ILD layers 136B, and on the top surfaces and the sidewalls of the source/drain features 132B2, as shown in FIGS. 1D-1F. In some embodiments, the ILD layers 140B are formed on the CESLs 138B to fill the spaces in the CESLs 138B and between the gate spacers 128B, as shown in FIGS. 1D-1F. In some embodiments, the source/drain features 132B1 and 132B2 are spaced apart from each other by the CESLs 138B and the ILD layers 140B.

In some embodiments, the semiconductor structures 100A and 100B further include a semiconductor layer 303A and a semiconductor layer 303B that are embedded inside the substrate 102, respectively. In some embodiments, the semiconductor layer 303A is divided into several segments that are embedded in the base portions 103A, as shown in FIGS. 1A-1C. In some embodiments, the semiconductor layer 303B is divided into several segments that are embedded in the base portions 103B, as shown in FIGS. 1D-1F. In other embodiments, the semiconductor layer 303A is embedded in a portion of the substrate 102 that is under the base portions 103A, and the semiconductor layer 303B is embedded in a portion of the substrate 102 that is under the base portions 103B.

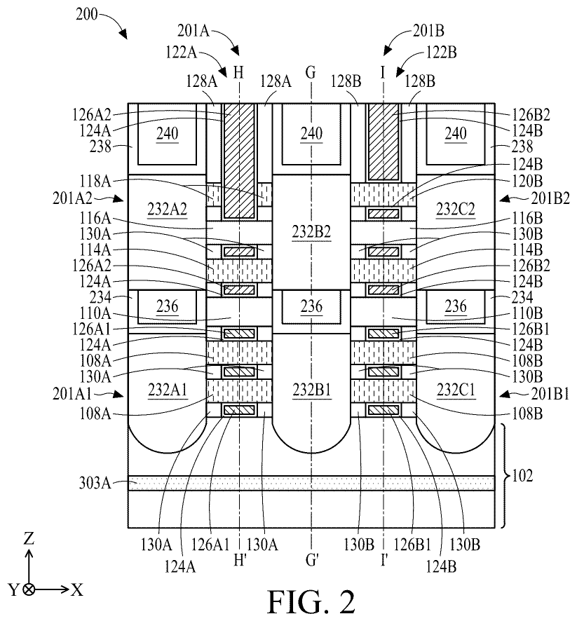

FIG. 2A illustrates a cross-sectional view of a semiconductor structure 200, in accordance with some alternative embodiments of the present disclosure. Referring to FIG. 2, the semiconductor structure 200 may include a CFET 201A and a CFET 201B that are arranged in the X-direction, in accordance with some embodiments. The CFET 201A has a lower device 201A1 and an upper device 101A2 disposed over (or vertically overlaps) the lower device 201A1 in the Z-direction, and the CFET 201B has a lower device 201B1 and an upper device 201B2 disposed over (or vertically overlaps) the lower device 201B1 in the Z-direction, as shown in FIG. 2. In some embodiments, the lower devices 201A1 and 201B1 may be PFETs, and the upper devices 201A2 and 201B2 may be NFETs. In other embodiments, the lower devices 201A1 and 201B1 may be NFETs and the upper device 201A2 and 201B2 may be PFETs.

The semiconductor structure 200 further includes the substrate 102 that includes a base portion protruding from the substrate 102, and the subsequent features for the CFETs 201A and 201B are formed over the base portion. In some embodiments, similar to the semiconductor structure 100, the semiconductor structure 200 also includes isolation structures 104. The configuration of the isolation structures 104 has been discussed above with reference to FIGS. 1A-1F, and is not repeated herein.

In some embodiments, similar to the CFET 101A, the CFET 201A also includes nanostructures 108A used for the lower devices 201A1, and includes nanostructure 114A used for the upper devices 201A2. The configurations of the nanostructures 108A and 114A have been discussed above with reference to FIGS. 1A-1C, and are not repeated herein. In some embodiments, similar to the CFET 101A, the CFET 201A also includes the middle insulator 110A, the ESL 116A, and the semiconductor segments 118A. The configurations of the middle insulator 110A, the ESL 116A, and the semiconductor segments 118A have been discussed above with reference to FIGS. 1A-1C, and are not repeated herein.

In some embodiments, similar to the CFET 101A, the CFET 201A also includes the gate structure 122A (including the gate dielectric layer 124A and the gate electrode layers 126A1 and 126A2), the gate spacers 128A, and the inner spacers 130A. The configurations of the gate structure 122A, the gate spacers 128A, and the inner spacers 130A have been discussed above with reference to FIGS. 1A-1C, and are not repeated herein.

In some embodiments, similar to the CFET 101B, the CFET 201B also includes nanostructures 108B used for the lower devices 201B1, and includes nanostructures 114B and 120B used for the upper devices 201B2. The configurations of the nanostructures 108B, 114B, and 120B have been discussed above with reference to FIGS. 1D-1F, and are not repeated herein. In some embodiments, similar to the CFET 101B, the CFET 201B also includes the middle insulator 110B and the ESL 116B. The configurations of the middle insulator 110B and the ESL 116B have been discussed above with reference to FIGS. 1D-1F, and are not repeated herein.

In some embodiments, similar to the CFET 101B, the CFET 201B also includes the gate structure 122B (including the gate dielectric layer 124B and the gate electrode layers 126B1 and 126B2), the gate spacers 128B, and the inner spacers 130B. The configurations of the gate structure 122B, the gate spacers 128B, and the inner spacers 130B have been discussed above with reference to FIGS. 1D-1F, and are not repeated herein.

In some embodiments, the CFET 201A includes a source/drain feature 232A1 disposed over the substrate 102, and a source/drain feature 232A2 disposed over (or vertically overlap) the source/drain features 232A1, as shown in FIG. 2. In some embodiments, the CFET 201A further includes a source/drain feature 232B1 disposed over the substrate 102, and a source/drain feature 232B2 disposed over (or vertically overlap) the source/drain features 232B1, as shown in FIG. 2. For the CFET 201A, the configurations of the source/drain features 232A1 and 232B1 are the same as or similar to those of the source/drain features 132A1, and the configurations of the source/drain features 232A2 and 232B2 are the same as or similar to those of the source/drain features 132A2. In some embodiments, the source/drain features 232A1 and 232B1 are disposed on opposite sides of the gate structures 122A (e.g., the gate electrode layers 126A1) in the X-direction to form lower devices 201A1, as shown in FIG. 2. Similarly, the source/drain features 232A2 and 232B2 are disposed on opposite sides of the gate structure 122A (e.g., the gate electrode layers 126A2) in the X-direction to form the upper devices 201A2, as shown in FIG. 2.

The nanostructures 108A may connect the source/drain feature 232A1 to the source/drain feature 232B1, and the nanostructure 114A may connect the source/drain feature 232A2 to the source/drain feature 232B2. Specifically, the source/drain features 232A1 and 232B1 are disposed on opposite sides of the nanostructures 108A in the X-direction, and the source/drain features 232A2 and 232B2 are disposed on opposite sides of the nanostructure 114A and the ESLs 116A in the X-direction. Therefore, the source/drain features 232A1 and 232B1 are attached and electrically connected to the nanostructures 108A in the X-direction, and the source/drain features 232A2 and 232B2 are attached and electrically connected to the nanostructure 114A in the X-direction. The semiconductor segments 118A and the ESL 116A are also attached to the source/drain features 232A2 and 232B2 in the X-direction.

In some embodiments, the CFET 201B includes a source/drain feature 232C1 disposed over the substrate 102, and a source/drain feature 232C2 disposed over (or vertically overlap) the source/drain features 232C1, as shown in FIG. 2. In some embodiments, the CFET 201B further includes the source/drain feature 232B1 and 232B2. For the CFET 201B, the configurations of the source/drain features 232B1 and 232C1 are the same as or similar to those of the source/drain features 132B1, and the configurations of the source/drain features 232B2 and 232C2 are the same as or similar to those of the source/drain features 132B2. In some embodiments, the source/drain features 232B1 and 232C1 are disposed on opposite sides of the gate structures 122B (e.g., the gate electrode layers 126B1) in the X-direction to form lower devices 201B1, as shown in FIG. 2. Similarly, the source/drain features 232B2 and 232C2 are disposed on opposite sides of the gate structure 122B (e.g., the gate electrode layers 126B2) in the X-direction to form the upper devices 201B2, as shown in FIG. 2.

The nanostructures 108B may connect the source/drain feature 232B1 to the source/drain feature 232C1, and the nanostructures 114B and 120B may connect the source/drain feature 232B2 to the source/drain feature 232C2. More specifically, the source/drain features 232B1 and 232C1 are disposed on opposite sides of the nanostructures 108B in the X-direction, and the source/drain features 232B2 and 232C2 are disposed on opposite sides of the nanostructures 114B and 120B and the ESLs 116B in the X-direction. Therefore, the source/drain features 232B1 and 232C1 are attached and electrically connected to the nanostructures 108B in the X-direction, and the source/drain features 232B2 and 232C2 are attached and electrically connected to the nanostructures 114B and 120B in the X-direction. The ESL 116B is also attached to the source/drain features 232B2 and 232C2 in the X-direction.

It should be noted that, although FIG. 2 shows the embodiments that the CFETs 201A and the 201B share the source/drain features 232B1 and 232B2, the CFETs 201A and the 201B may each includes its own source/drain features without sharing common source/drain features with each other. For example, the semiconductor structure 200 may include an additional isolation structure the separates the CFET 201A from the CFET 201B, and the CFET 201A may include four source/drain features that are different than the four source/drain features of the CFET 201B.

Similar to the source/drain features 132A1, 132A2, 132B1, and 132B2, the source/drain features 232A1, 232A2, 232B1, 232B2, 232C1, and 232C2 may also be referred to as source/drain, or source/drain regions. In some embodiments, source/drain feature(s) may refer to a source or a drain, individually or collectively dependent upon the context. In some embodiments, the semiconductor structure 200 further include undoped epitaxial layers (not shown) and bottom isolation layers (not shown) that have been discussed above with reference to the semiconductor structure 100.

In some embodiments, the semiconductor structure 200 may further include CESLs 234 and ILD layers 236. The CESLs 234 and the ILD layers 236 may be formed between the source/drain features 232A1 and 232A2, between the source/drain features 232B1 and 232B2, and between the source/drain features 232C1 and 232C2 in the Z-direction. The configurations of the CESLs 234 and the ILD layers 236 are the same as or similar to those of the CESLs 134A (or CESLs 134B) and the ILD layers 136A (or ILD layers 136B), and are not repeated herein.

In some embodiments, the semiconductor structure 200 may further include CESLs 238 and ILD layers 240 on the CESLs 238. In some embodiments, the CESLs 238 are formed over the source/drain features 232A2, 232B2, and 232C2, the CESLs 234, and the ILD layers 236. The configurations of the CESLs 238 and the ILD layers 240 are the same as or similar to those of the CESLs 138A (or CESLs 138B) and the ILD layers 140A (or ILD layers 140B), and are not repeated herein.

For the semiconductor structure 200, the cross-sectional view along line G-G′ of FIG. 2 is the same as or similar to FIG. 1B or FIG. 1E, the cross-sectional view along line H-H′ of FIG. 2 is the same as or similar to FIG. 1C, and the cross-sectional view along line I-I′ of FIG. 2 is the same as or similar to FIG. 1F. As shown in FIG. 2, the CFETs with different numbers of nanostructures can be formed adjacent to each other, and/or can be formed in the same fin structure. For example, the CFET 201A with less nanostructures and the CFET 201B with more nanostructures are formed adjacent to each other, and are formed in the same fin structure.

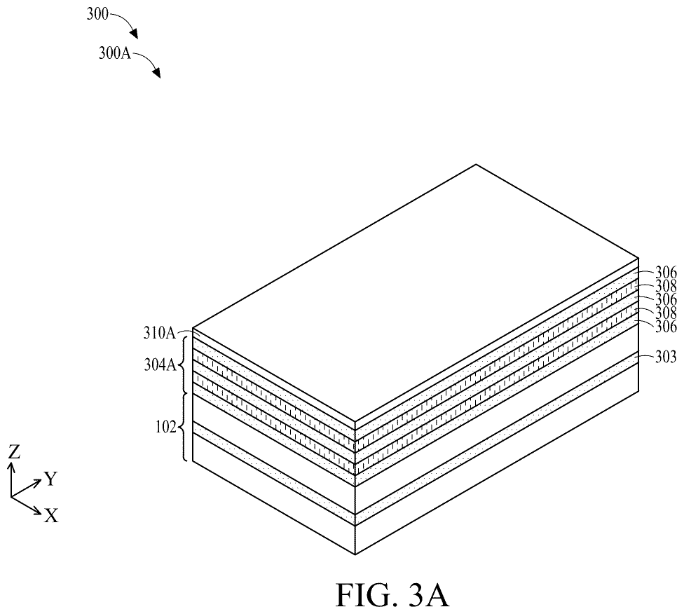

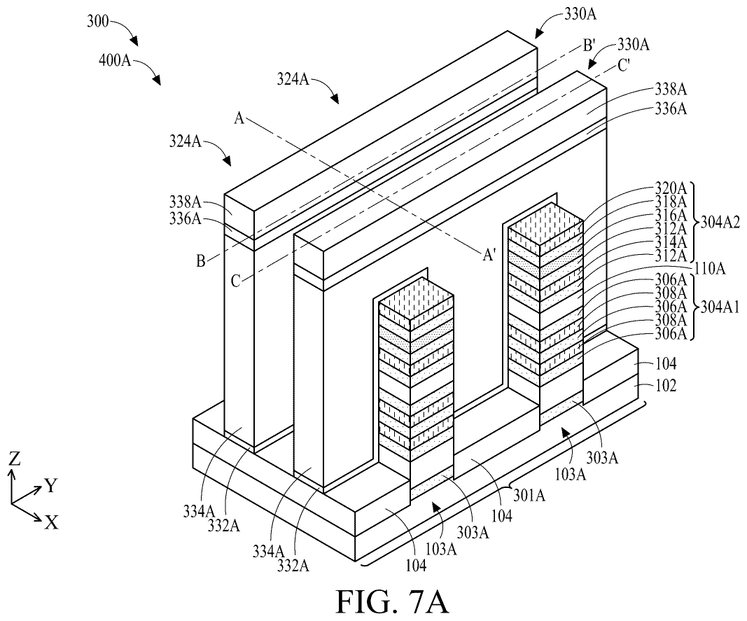

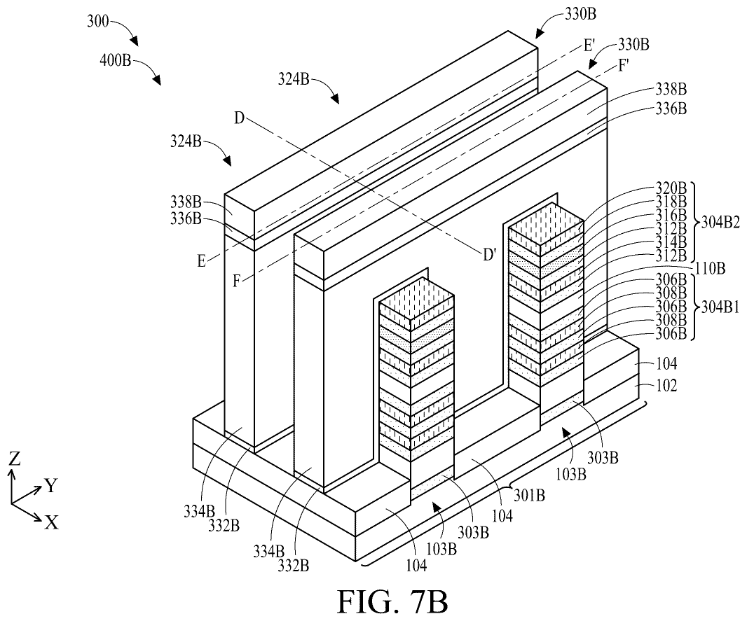

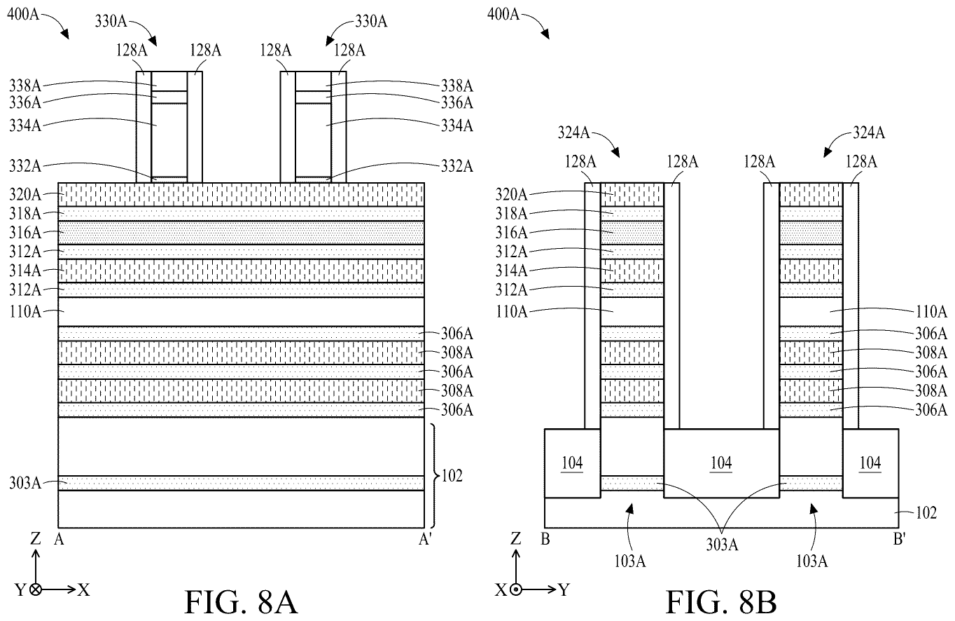

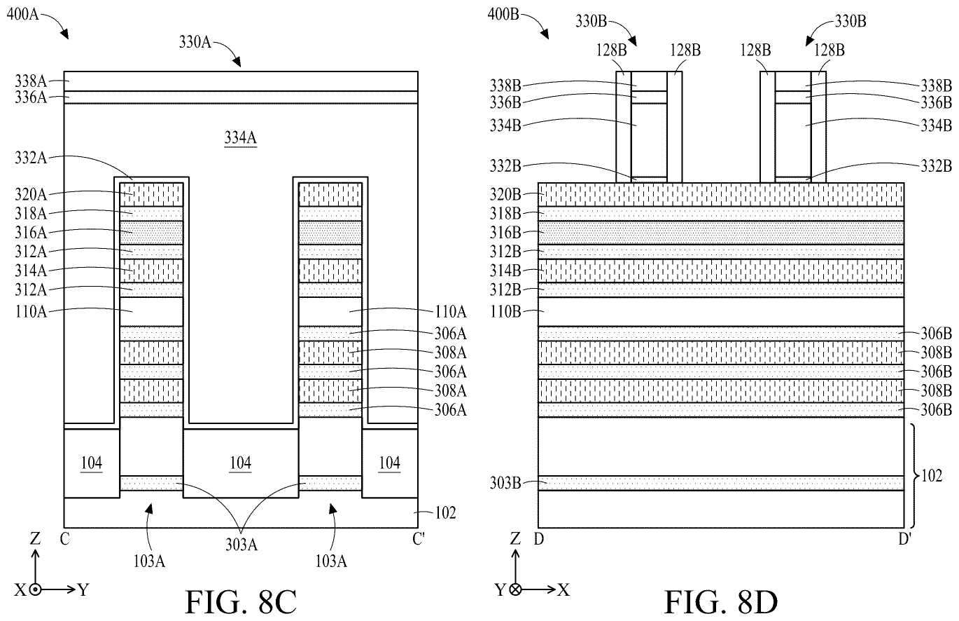

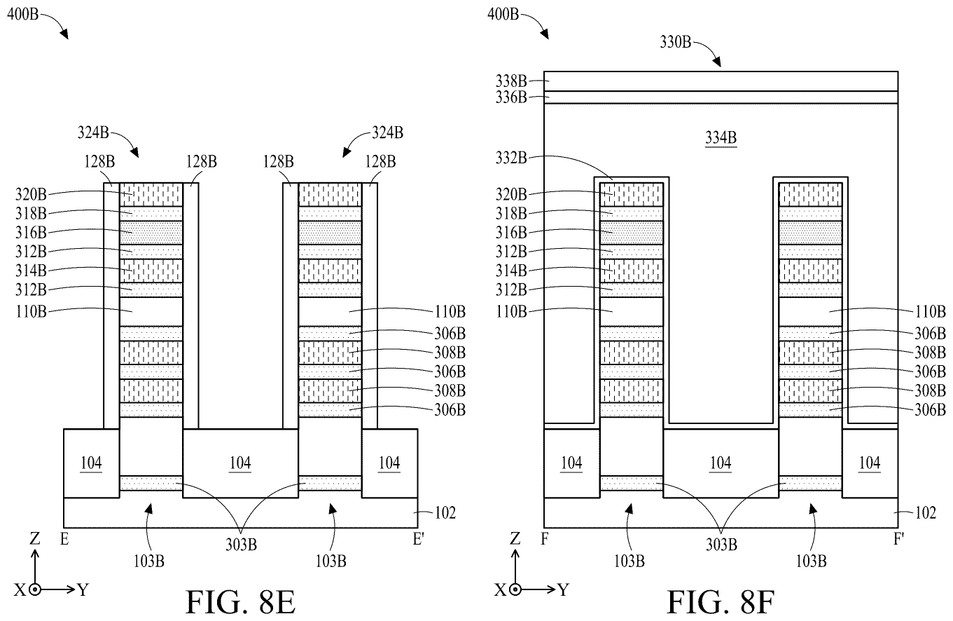

The formation of the semiconductor structure (e.g., semiconductor structures 100 and 200) are described in detail in below. The formation of the semiconductor structure starts from a workpiece 300. FIGS. 3A, 3B, 4, 5, 6A, 6B, 7A, and 7B are perspective views of the workpiece 300 at various fabrication stages, in accordance with some embodiments. FIGS. 8A, 9A, 10A, 11A, 12A, 13A, 14A, 15A, 16A, 17A, and 18A are X-Z cross-sectional views of the workpiece 300 at various fabrication stages along line A-A′ of FIG. 7A, in accordance with some embodiments. FIGS. 8B, 9B, 10B, 11B, 12B, 13B, 14B, 15B, 16B, 17B, and 18B are Y-Z cross-sectional views of the workpiece 300 at various fabrication stages along line B-B′ of FIG. 7A, in accordance with some embodiments. FIGS. 8C, 15C, 16C, 17C, and 18C are Y-Z cross-sectional views of the workpiece 300 at various fabrication stages along line C-C′ of FIG. 7A, in accordance with some embodiments. FIGS. 8D, 9C, 10C, 11C, 12C, 13C, 14C, 15D, 16D, 17D and 18D are X-Z cross-sectional views of the workpiece 300 at various fabrication stages along line D-D′ of FIG. 7B, in accordance with some embodiments. FIGS. 8E, 9D, 10D, 11D, 12D, 13D, 14D, 15E, 16E, 17E and 18E are Y-Z cross-sectional views of the workpiece 300 at various fabrication stages along line E-E′ of FIG. 7B, in accordance with some embodiments. FIGS. 8F, 15F, 16F, 17F, and 18F are Y-Z cross-sectional views of the workpiece 300 at various fabrication stages along line F-F′ of FIG. 7B, in accordance with some embodiments.

Referring to FIGS. 3A and 3B, the workpiece 300 including a first epitaxial structure 300A and a second epitaxial structure 300B is provided, in accordance with some embodiments. In some embodiments, the first epitaxial structure 300A includes a substrate 102, a stack 304A over the substrate 102, and a bonding layer 310A over the stack 304A, as shown in FIG. 3A. In some embodiments, the second epitaxial structure 300B includes a substrate 302, a stack 304B over the substrate 302, and a bonding layer 310B over the stack 304B, as shown in FIG. 3B. In some embodiments, the substrate 102 further includes a semiconductor layer 303 embedded inside the substrate 102, and the substrate 302 further includes a semiconductor layer 305 embedded inside the substrate 302, as shown in FIGS. 3A and 3B.

In some embodiments, the stack 304A includes semiconductor layers 306 and semiconductor layers 308 that are stacked in an alternating manner in the Z-direction. In some embodiments, the bottommost semiconductor layer 306 is in contact with the substrate 102, and the topmost semiconductor layer 306 is in contact with the bonding layer 310A. In some embodiments, the stack 304B includes a semiconductor layer 318 formed on the substrate 302, a semiconductor layer 316 formed on the semiconductor layer 318, and semiconductor layers 312 and a semiconductor layer 314 that are stacked in an alternating manner and over the semiconductor layer 316 in the Z-direction. In some embodiments, the bottommost semiconductor layer 312 is in contact with the semiconductor layer 316, and the topmost semiconductor layer 312 is in contact with the bonding layer 310B.

The semiconductor layers 308 are used for the nanostructures 108A and 108B of the lower devices 101A1 and 101B1, and the semiconductor layer 314 is used for the nanostructures 114A and 114B of the upper devices 101A2 and 101B2. It should be noted that, three layers of the semiconductor layers 306 and two layers of the semiconductor layers 308 are shown in FIG. 3A, and two layers of the semiconductor layers 312 and one layer of the semiconductor layers 314 are shown in FIG. 3B, which are for illustrative purposes only and not intended to be limiting beyond what is specifically recited in the claims. The number of the semiconductor layers depends on the desired number of channel members for the semiconductor device. For example, the second epitaxial structure 300B may include two or more layers of the semiconductor layers 314 to provide more nanostructures 114A and 114B in the semiconductor structures.

In some embodiments, the substrate 102 contains a semiconductor material, such as bulk silicon (Si). In other embodiments, the substrate 102 may include other semiconductors such as Ge, SiGe, or a III-V semiconductor material. Example III-V semiconductor materials may include GaAs, InP, GaP, GaN, GaAsP, AlInAs, AlGaAs, GaInP, and InGaAs. The substrate 102 may also include an insulating layer, such as a silicon oxide layer, to have a silicon-on-insulator (SOI) structure or a germanium-on-insulator (GOI) structure. In some embodiments, the substrate 102 may include one or more well regions for forming different types of devices. For example, the well regions may be n-type well regions doped with an n-type dopant (e.g., phosphorus (P) or arsenic (As)) or p-type well regions doped with a p-type dopant (e.g., boron (B) or indium (In)). The n-type and p-type well regions may be formed by using ion implantation or thermal diffusion.

In some embodiments, the substrate 302 and the semiconductor layers 308 and 314 have a first semiconductor material; the semiconductor layers 306, 312, and 318 have a second semiconductor material; and the semiconductor layer 316 have a third semiconductor material. The first, second, and third semiconductor materials may have different semiconductor compositions. In some embodiments, the first semiconductor material is Si, and the second and third semiconductor materials are SiGe. In these embodiments, the additional germanium content in the second and third semiconductor materials allows selective removal or recess of the semiconductor layers 306, 312, 318, and 316 without substantial damages to the semiconductor layers 308 and 314. In some embodiments, the semiconductor layers 303 and 305 have a semiconductor material that is the same as the semiconductor layers 306, 312, and 318.

In some embodiments, the second and third semiconductor materials are SiGe, and the Ge concentration of the third semiconductor material is higher than the Ge concentration of the second semiconductor material. The different germanium contents may provide etching selectivity between the second semiconductor material (i.e., the semiconductor layers 306, 312, and 318) and the third semiconductor material (i.e., the semiconductor layer 316). For example, the semiconductor layer 316 may be substantially completely removed while the semiconductor layers 306, 312, and 318 are substantially not etched. In some embodiments, the second semiconductor material may have a Ge concentration in a range from about 20% to about 30%, and the third semiconductor material may have a Ge concentration in a range from about 35% to about 50%.

In some embodiments, the semiconductor layers 306 and 308 are epitaxially grown on the substrate 102 through an epitaxial growth, and the semiconductor layers 312, 314, 316 and 318 are epitaxially grown on the substrate 302 through the epitaxial growth. The epitaxial growth may include vapor-phase epitaxy (VPE), metal-organic CVD (MOCVD), molecular beam epitaxy (MBE), although other deposition processes, such as chemical vapor deposition (CVD), low pressure CVD (LPCVD), plasma-enhanced CVD (PECVD), atomic layer deposition (ALD), ultrahigh vacuum CVD (UHVCVD), remote plasma CVD (RPCVD), a combination thereof, or the like, may also be utilized.

In some embodiments, the bonding layers 310A and 310B include a dielectric material such as SiO, SiN, SiOCN, SiON, AlN, AlO, another suitable material, or a combination thereof. In some embodiments, the bonding layer 310A is deposited on the stack 304A (i.e., on the topmost semiconductor layer 306) and the bonding layer 310B is deposited on the stack 304B (i.e., on the topmost semiconductor layer 312) through a deposition process. The deposition process may include CVD, ALD, high-density plasma CVD (HDPCVD), MOCVD, RPCVD, PECVD, LPCVD, atomic layer CVD (ALCVD), atmospheric pressure CVD (APCVD), subatmospheric CVD (SACVD), flowable CVD (FCVD), spin-on coating, and/or other suitable process.

In some embodiments, each of the semiconductor layers 308 and 314 has a first thickness, and each of the semiconductor layers 306, 312, and 318 has a second thickness. In some embodiments, the ratio of the first thickness to the second thickness is in a range from about 0.5 to about 2. In some embodiments, the semiconductor layer 316 has a thickness in a range from about 5 nm to about 20 nm. In some embodiments, each of the bonding layers 310A and 310B has a thickness in a range from about 5 nm to about 30 nm.

Referring to FIG. 4, the first epitaxial structure 300A and the second epitaxial structure 300B are bonded together to constitute a third epitaxial structure 300C, in accordance with some embodiments. In some embodiments, the first epitaxial structure 300A and the second epitaxial structure 300B are bonded together by bonding the bonding layer 310A with the bonding layer 310B using a suitable technique such as dielectric-to-dielectric bonding, or the like. The dielectric-to-dielectric bonding may include applying a surface treatment to the bonding layers 310A and 310B. The surface treatment may include a plasma treatment and a cleaning process following the plasma treatment. Then, the second epitaxial structure 300B is flipped. Afterward, the first epitaxial structure 300A (including the bonding layer 310A) is aligned with the second epitaxial structure 300B (including the bonding layer 310B), and the first epitaxial structure 300A and the second epitaxial structure 300B are pressed against each other to initiate a pre-bonding. After the pre-bonding, an annealing process may be applied to heat the first epitaxial structure 300A and the second epitaxial structure 300B, so as to form the third epitaxial structure 300C.

After bonding, the bonding layers 310A and 310B are bonded together as a single layer, which functions as the middle insulators 110A and 110B and thus will be referred to as the middle insulator 110 below. In some embodiments, in the third epitaxial structure 300C, the middle insulator 110 is formed on the stack 304A and the stack 304B is formed on the middle insulator 110. In further embodiments, the middle insulator 110 is in contact with the topmost semiconductor layer 306 of the stack 304A and in contact with the bottommost semiconductor layer 312 of the stack 304B.

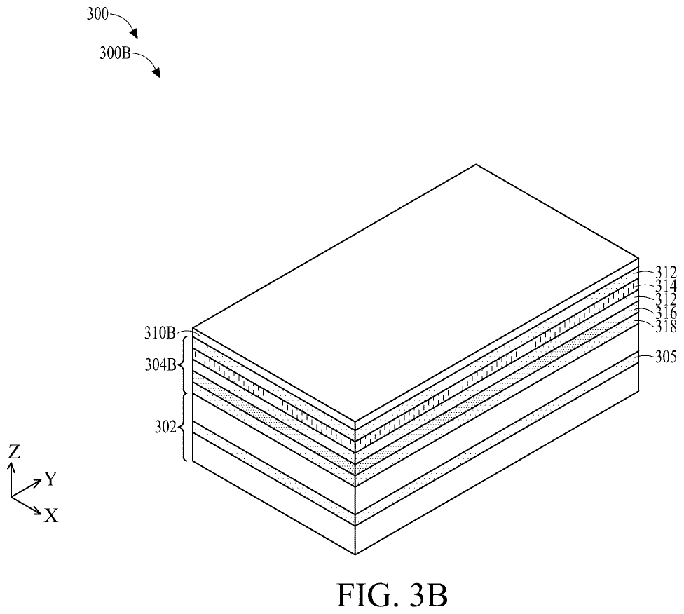

Referring to FIG. 5, the third epitaxial structure 300C is thinned by a thinning process combining one or more CMP processes and one or more etching processes, in accordance with some embodiments. In some embodiments, the top portion of the third epitaxial structure 300C is thinned to partially remove the substrate 302 through the thinning process. After the thinning process, a portion of the substrate 302 (including semiconductor layer 305) are removed, and the remaining portion of the substrate 302 forms a semiconductor layer 320 on the semiconductor layer 318, as shown in FIG. 5. In some embodiments, the thickness and the material of the semiconductor layer 320 are the same as that of the semiconductor layers 308 and 314. In some embodiments, for the purpose of simplicity, the semiconductor layer 320 may be assigned to the stack 304B. That is, the stack 304B may include the semiconductor layers 312, 314, 316, 318, and 320 after the fabrication stage shown in FIG. 5.

In some embodiments, for patterning purposes, a hard mask layer 322 may be formed on the stack 304B, that is, formed on the semiconductor layer 320. The hard mask layer 322 may be a single layer structure or a multi-layer structure. In some embodiments, the hard mask layer 322 is a single layer structure and includes a silicon germanium layer. In some embodiments, the hard mask layer 322 is a multi-layer structure and includes a silicon nitride layer and a silicon oxide layer over the silicon nitride layer. In other embodiments, the hard mask layer 322 is a multi-layer structure and includes a silicon germanium layer and a silicon layer over the silicon germanium layer.

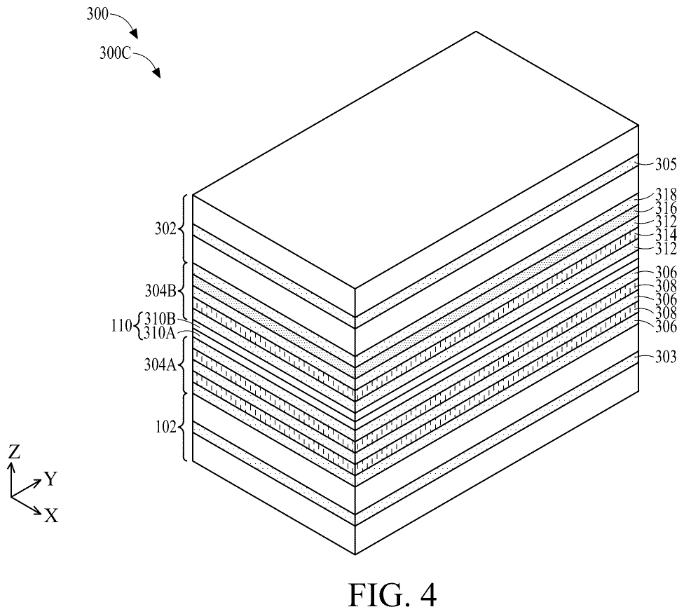

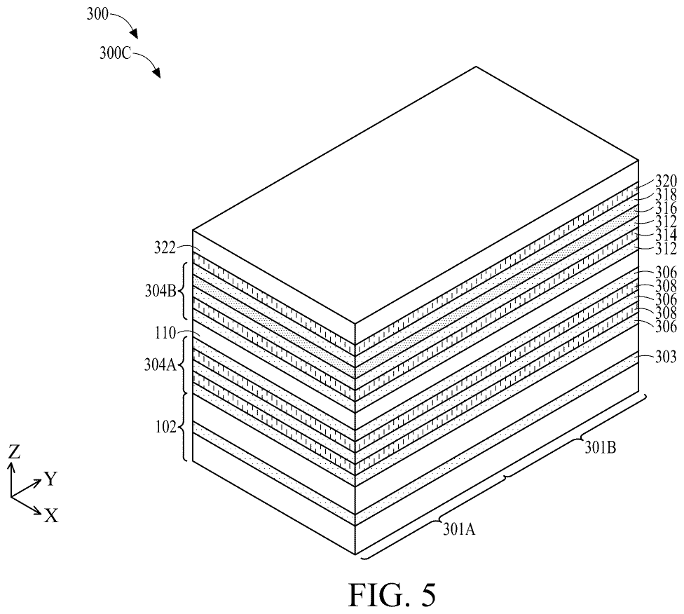

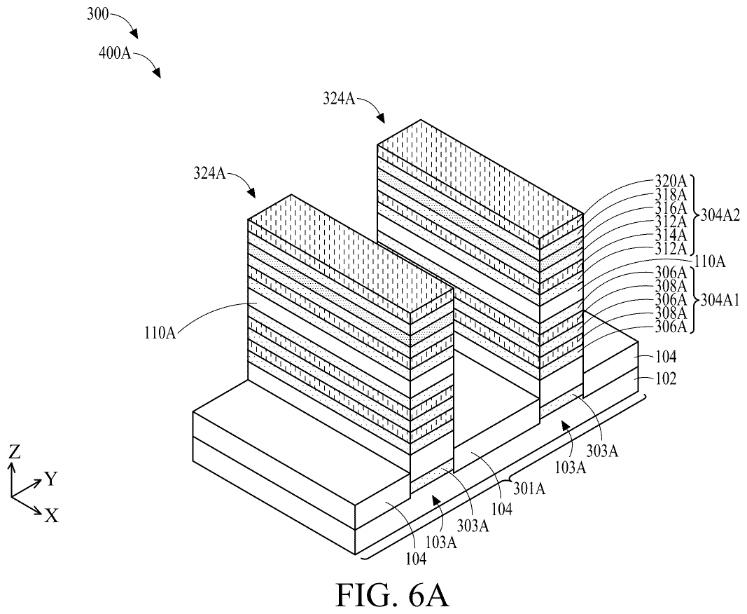

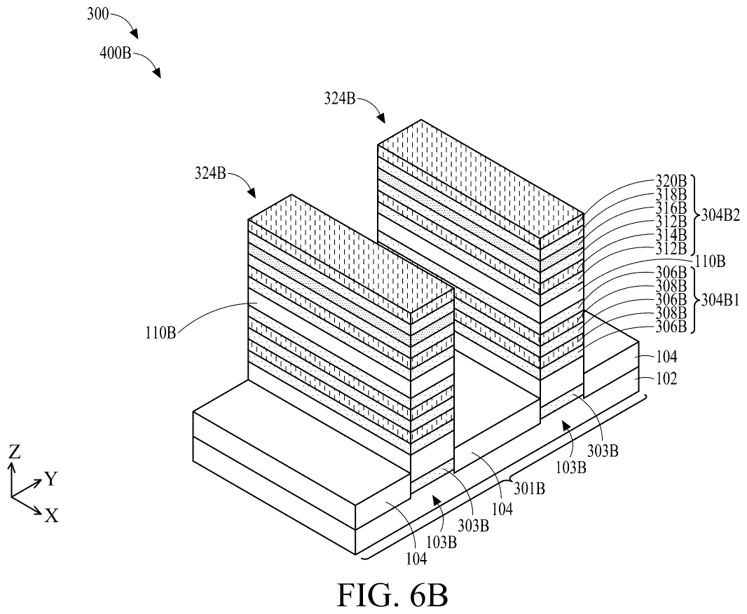

Referring to FIGS. 6A and 6B, the third epitaxial structure 300C of the workpiece 300 is formed into semiconductor structures 400A and 400B, in accordance with some embodiments. In some embodiments, the semiconductor structure 400A is formed in the region 301A of the workpiece 300, and the semiconductor structure 400B is formed in the region 301B of the workpiece 300. In some embodiments, the substrate 102, the stacks 304A and 304B, the middle insulator 110, and the hard mask 322 are patterned to form fin structures 324A of the semiconductor structure 400A in the region 301A, and to form fin structures 324B of the semiconductor structure 400B in the region 301B, as shown in FIGS. 6A and 6B.

In some embodiments, in the semiconductor structure 400A, each of the fin structures 324A includes the base portion 103A formed from a portion of the substrate 102 and a stack portion over the base portion. The stack portion may include a first stack 304A1 formed from the stack 304A, a middle insulator 110A formed from the middle insulator 110, and a second stack 304A2 formed from the stack 304B. The first stack 304A1 is formed on the base portion 103A, the middle insulator 110A is formed on the first stack 304A1, and the second stack 304A2 is formed on the middle insulator 110A.

In some embodiments, the base portion 103A includes a semiconductor layer 303A embedded in the base portion 103A. In other embodiments, the semiconductor layer 303A is embedded in a portion of the substrate 102 that is under the base portions 103A. In some embodiments, the first stack 304A1 includes semiconductor layers 306A and 308A that are stacked in the Z-direction in an alternating manner. The semiconductor layers 306A and 308A are formed from the semiconductor layers 306 and 308, respectively. In some embodiments, the second stack 304A2 includes semiconductor layers 312A and a semiconductor layer 314A that are stacked in an alternating manner, a semiconductor layer 316A formed on the topmost semiconductor layer 312A, a semiconductor layer 318A formed on the semiconductor layer 316A, and a semiconductor layer 320A formed on the semiconductor layer 318A in the Z-direction. The semiconductor layers 303A, 312A, 314A, 316A, 318A, and 320A are formed from the semiconductor layers 303, 312, 314, 316, 318, and 320, respectively.

In some embodiments, in the semiconductor structure 400B, each of the fin structures 324B includes the base portion 103B formed from a portion of the substrate 102 and a stack portion over the base portion. The stack portion may include a first stack 304B1 formed from the stack 304A, a middle insulator 110B formed from the middle insulator 110, and a second stack 304B2 formed from the stack 304B. The first stack 304B1 is formed on the base portion 103B, the middle insulator 110B is formed on the first stack 304B1, and the second stack 304B2 is formed on the middle insulator 110B.

In some embodiments, the base portion 103B includes a semiconductor layer 303B embedded in the base portion 103B. In other embodiments, the semiconductor layer 303B is embedded in a portion of the substrate 102 that is under the base portions 103B. In some embodiments, the first stack 304B1 includes semiconductor layers 306B and 308B that are stacked in the Z-direction in an alternating manner. The semiconductor layers 306B and 308B are formed from the semiconductor layers 306 and 308, respectively. In some embodiments, the second stack 304B2 includes semiconductor layers 312B and a semiconductor layer 314B that are stacked in an alternating manner, a semiconductor layer 316B formed on the topmost semiconductor layer 312B, a semiconductor layer 318B formed on the semiconductor layer 316B, and a semiconductor layer 320B formed on the semiconductor layer 318B in the Z-direction. The semiconductor layers 303B, 312B, 314B, 316B, 318B, and 320B are formed from the semiconductor layers 303, 312, 314, 316, 318, and 320, respectively.

In some embodiments, the base portions 103A and 103B protrude from the substrate 102. The fin structures 324A extend lengthwise in the X-direction and extend vertically in the Z-direction over the substrate 102, and are arranged in the Y-direction. Similarly, the fin structures 324B extend lengthwise in the X-direction and extend vertically in the Z-direction over the substrate 102, and are arranged in the Y-direction. Although the two fin structures 324A and two fin structures 324B are formed and shown herein, more fin structures may be formed, such as three or more fin structures.

The fin structures 324A and 324B (may be collectively referred to as fin structures 324) may be patterned using suitable processes including double-patterning or multi-patterning processes. For example, in some embodiments, a material layer is formed over the stack 304B and patterned using a photolithography process. Spacers are formed alongside the patterned material layer using a self-aligned process. The material layer is then removed, and the remaining spacers, or mandrels, may then be used to pattern the fin structures 324 by etching the stack 304B, the middle insulator 110, the stack 304A, and the substrate 102. The etching process may include dry etching, wet etching, reactive ion etching (RIE), and/or other suitable processes.

Still referring to FIGS. 6A and 6B, the isolation structures 104 are formed, in accordance with some embodiments. After forming the fin structures 324, the hard mask layers 322 over the fin structures 324 are removed, and the isolation structures 104 are formed over the substrate 102. In some embodiments, the isolation structures 104 extend in the X-direction and are arranged with the fin structures 324 in the Y-direction. In other words, the isolation structures 104 are formed on opposite sides of the fin structures 324 in the Y-direction. In some aspects, the isolation structures 104 are formed around the fin structures 324.

The isolation structures 104 may include different structures, such as shallow trench isolation (STI) structures, deep trench isolation (DTI) structures, and/or local oxidation of silicon (LOCOS) structures. In some embodiments, the STI structures include a single layer structure. In other embodiments, the STI structures include a multi-layer structure that has a bulk dielectric layer disposed over a liner dielectric layer.

In some embodiments, the dielectric material for the isolation structures 104 is first deposited over the workpiece 300. Specifically, the dielectric material is deposited and formed over the fin structures 324 and the substrate 102 to cover the fin structures 324 and the substrate 102. In some embodiments, the dielectric material is formed to wrap around the fin structures 324. In some embodiments, the dielectric material may include silicon oxide (SiO₂), silicon nitride (Si₃N₄), silicon oxynitride (SiON), fluorine-doped silicate glass (FSG), a low-k dielectric material, other suitable materials, or combinations thereof. Exemplary low-k dielectric materials include carbon doped silicon oxide, xerogel, aerogel, amorphous fluorinated carbon, parylene, BCB-based dielectric material, polyimide, other low-k dielectric materials, or combinations thereof.

In some embodiments, the dielectric material is deposited using a deposition process, such as CVD, ALD, HDPCVD, MOCVD, RPCVD, PECVD, LPCVD, ALCVD, APCVD, SACVD, FCVD, spin-on coating, and/or other suitable process. The deposited dielectric material is then thinned and planarized, for example by a CMP process, until the hard mask layers 322 are removed. The planarized dielectric material is further recessed by a dry etching process, a wet etching process, or a combination thereof to form the isolation structures 104. In some embodiments, before forming the isolation structures 104, a liner layer may be conformally deposited over the substrate 102 by a deposition process, such as CVD, ALD, HDPCVD, MOCVD, RPCVD, PECVD, LPCVD, ALCVD, APCVD, FCVD, or combinations thereof. In some embodiments, the stack portions of the fin structures 324 rise above the isolation structures 104 while the base portions 103A and 103B are surrounded by the isolation structures 104, as shown in FIGS. 6A and 6B. In other words, the top surface of the substrate 102 is higher than the top surfaces of the isolation structures 104.

Referring to FIGS. 7A and 7B, dummy gate structures 330A are formed over the fin structures 324A and the isolation structures 104 in the region 301A, and dummy gate structures 330B are formed over the fin structures 324B and the isolation structures 104 in the region 301B, in accordance with some embodiments. In some embodiments, the dummy gate structures 330A and 330B (may be collectively referred to as dummy gate structures 330) are configured to extend lengthwise in the Y-direction, and to wrap around the top surfaces and the side surfaces of the fin structures 324A and 324B, respectively. In some embodiments, to form the dummy gate structures 330, a dummy gate dielectric material for dummy gate dielectric layers 332A and 332B is first formed over the fin structures 324A and 324B and the isolation structures 104. In some embodiments, the dummy gate dielectric material may include, for example, a dielectric material such as a nitride (e.g., SiN, SiON), a carbide (e.g., silicon carbide (SiC)), an oxide (e.g., SiO₂), or other suitable material.

Then, in some embodiments, a dummy gate electrode material for dummy gate electrode layers 334A and 334B is formed on the dummy gate dielectric material. The dummy gate electrode material may include a conductive material selected from a group composed of polysilicon, W, Al, Cu, AlCu, Ti, TiAlN, TaC, TaCN, TaSiN, Mn, Zr, TiN, Ta, TaN, Co, Ni, and/or combinations thereof. The dummy gate electrode material and/or the dummy gate dielectric material may be formed by way of a thermal oxidation process and/or a deposition process (e.g., physical vapor deposition (PVD), CVD, PECVD, and ALD).

Afterward, hard masks 336A and 336B are formed over the dummy gate electrode material, and hard masks 338A and 338B are formed over the hard masks 336A and 336B. In some embodiments, the hard masks 336A, 336B, 338A, and 338B may be formed using photolithography and etching processes. In some embodiments, the hard masks 336A, 336B, 338A, and 338B may include photoresist materials or hard mask materials. In some embodiments, the hard masks 336A and 336B may be a silicon nitride layer, and the hard masks 338A and 338B may be a silicon oxide layer.

After forming the hard masks 336A, 336B, 338A, and 338B, a removal process (e.g., etching) may be performed to remove portions of the dummy gate electrode material and the dummy gate dielectric material that are not directly underlie the hard masks 336A, 336B, 338A, and 338B. After the removal process, the dummy gate dielectric layers 332A and 332B are formed from the dummy gate dielectric material and the dummy gate electrode layers 334A and 334B are formed from the dummy gate electrode material, thereby forming the dummy gate structures 330A and 330B. Each of the dummy gate structures 330A has the dummy gate dielectric layer 332A, the dummy gate electrode layer 334A, and the hard masks 336A and 338A. Similarly, each of the dummy gate structures 330B has the dummy gate dielectric layer 332B, the dummy gate electrode layer 334B, and the hard masks 336B and 338B.

The dummy gate structures 330A and 330B may undergo a gate replacement process through subsequent processing to form metal gates, such as a high-k metal gate, as discussed in greater detail below. FIG. 7A shows that the semiconductor structure 400A of the workpiece 300 has two dummy gate structures 330A, and FIG. 7B shows that the semiconductor structure 400B of the workpiece 300 has two dummy gate structures 330B. In some embodiments, in the semiconductor structures 400A and 400B, less or more dummy gate structures may be formed for one or more transistors sharing source/drain regions.

Referring to FIGS. 8A-8F, after the formation of the dummy gate structures 330A and 330B, gate spacers 128A and 128B are formed, in accordance with some embodiments. In some embodiments, the gate spacers 128A are formed on opposite sidewalls of the fin structures 324A, on opposite sidewalls of the dummy gate structures 330A, and over the top surface of the semiconductor layers 320A, as shown in FIGS. 8A-8C. In some embodiments, the gate spacers 128B are formed on opposite sidewalls of the fin structures 324B, on opposite sidewalls of the dummy gate structures 330B, and over the top surface of the semiconductor layers 320B, as shown in FIGS. 8D-8F. The gate spacers 128A and 128B may include Si₃N₄, SiO₂, SiC, silicon oxycarbide (SiOC), SiON, silicon carbon nitride (SiCN), silicon oxycarbon nitride (SiOCN), carbon doped oxide, nitrogen doped oxide, porous oxide, or combinations thereof. In some embodiments, the gate spacers 128A and 128B include a low-k dielectric material, such as those described herein. Each of the gate spacers 128A and 128B may include a single layer or a multi-layer structure.

In some embodiments, the gate spacers 128A and 128B may be formed by conformally depositing a spacer layer of dielectric material over the fin structures 324A and 324B and the dummy gate structures 330A and 330B, followed by an anisotropic etching process to remove horizontal portions of the spacer layer from the top surfaces of the isolation structures 104, the fin structures 324A and 324B, and the dummy gate structures 330A and 330B. After the anisotropic etching process, the portions of the spacer layer on the sidewall surfaces of the fin structures 324A and the dummy gate structures 330A substantially remain and become the gate spacers 128A. Similarly, the portions of the spacer layer on the sidewall surfaces of the fin structures 324B and the dummy gate structures 330B substantially remain and become the gate spacers 128B. In some embodiments, the anisotropic etching process is a dry (e.g., plasma) etching process. Additionally or alternatively, the formation of the gate spacers 128A and 128B may also involve chemical oxidation, thermal oxidation, CVD, PVD, ALD, HDPCVD, MOCVD, RPCVD, PECVD, LPCVD, ALCVD, APCVD, FCVD, and/or other suitable methods.

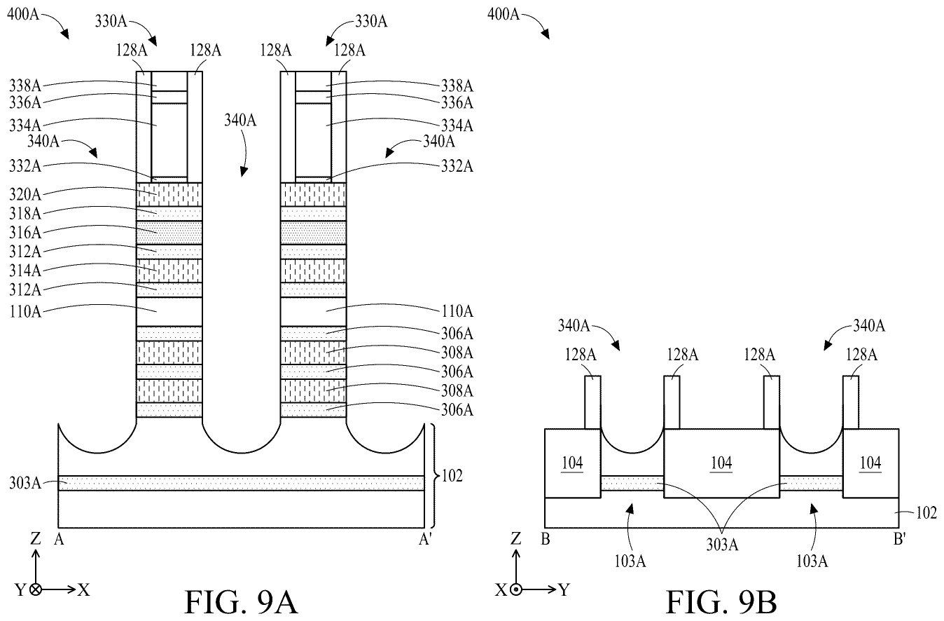

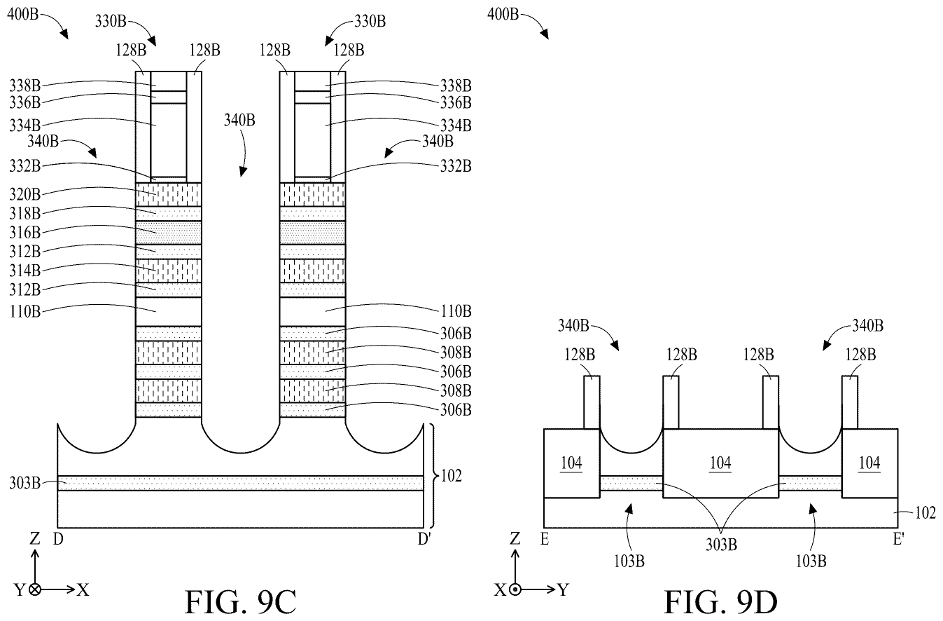

Referring to FIGS. 9A-9D, the fin structures 324A and 324B are recessed, so as to form source/drain trenches 340A in the fin structures 324A and form source/drain trenches 340B in the fin structures 324B, in accordance with some embodiments. In some embodiments, in each of the fin structures 324A, the source/drain trenches 340A are formed on opposite sides of the dummy gate structure 330A in the X-direction. In some embodiments, in each of the fin structures 324B, the source/drain trenches 340B are formed on opposite sides of the dummy gate structure 330B in the X-direction. Specifically, the source/drain trenches 340A and 340B may be formed by performing one or more etching processes. The etching processes may remove portions of the semiconductor layers 306A, 308A, 312A, 314A, 316A, 318A, and 320A, the middle insulators 110A, and the substrate 102 that the dummy gate structures 330A and the gate spacers 128A do not cover or vertically overlap. The etching processes may further remove portions of the semiconductor layers 306B, 308B, 312B, 314B, 316B, 318B, and 320B, the middle insulators 110B, and the substrate 102 that the dummy gate structures 330B and the gate spacers 128B do not cover or vertically overlap.

In some embodiments, a single etchant may be used to remove the substrate 102, the middle insulators 110A and 110B, and the semiconductor layers 306A, 306B, 308A, 308B, 312A, 312B, 314A, 314B, 316A, 316B, 318A, 318B, 320A, and 320B. In other embodiments, multiple etchants may be used to perform the etching processes. In some embodiments, portions of the gate spacers 128A formed on opposite sidewalls of the fin structures 324A in the Y-direction and portions of the gate spacers 128B formed on opposite sidewalls of the fin structures 324B in the Y-direction are partially etched during the etching processes. In these embodiments, the heights of the gate spacers 128A on opposite sidewalls of the fin structures 324A in the Y-direction and the heights of the gate spacers 128B on opposite sidewalls of the fin structures 324B in the Y-direction are reduced, as shown in FIGS. 9B and 9D.

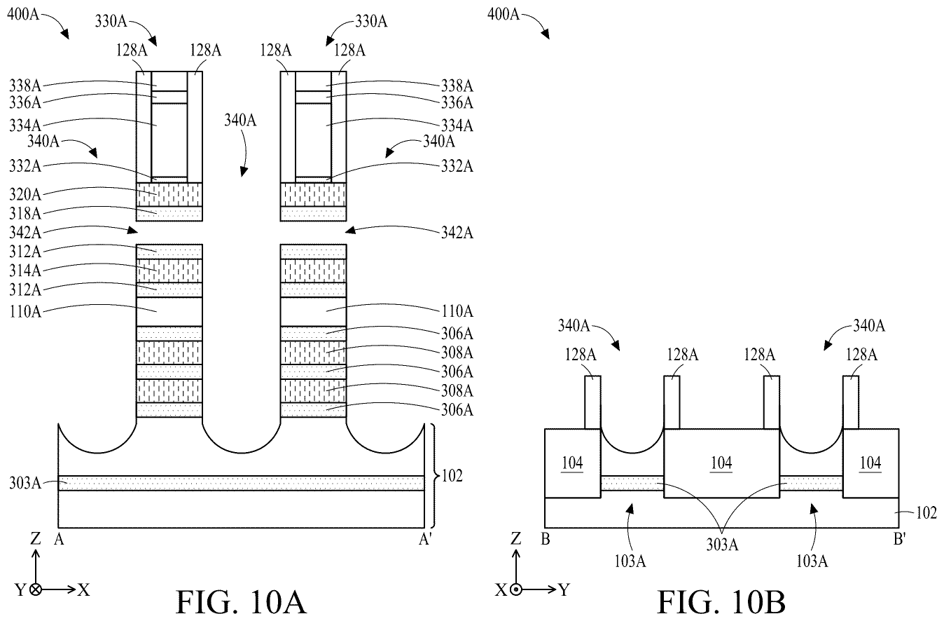

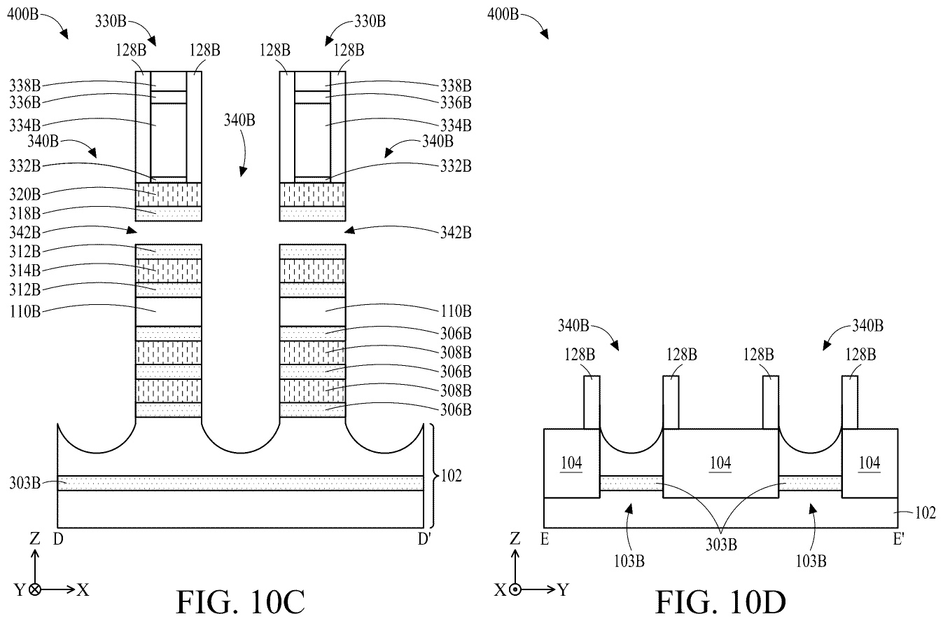

Referring to FIGS. 10A-10D, the semiconductor layers 316A are removed to form middle recesses 342A, and the semiconductor layers 316B are removed to form middle recesses 342B, in accordance with some embodiments. In some embodiments, the semiconductor layers 316A exposed in the source/drain trenches 340A and the semiconductor layers 316B exposed in the source/drain trenches 340B are removed through a selective etching process, and other semiconductor layers are not etched. More specifically, the selective etching process is performed that selectively etches the semiconductor layers 316A and 316B through the source/drain trenches 340A and 340B, with minimal etching (or substantially no etching) of the substrate 102, the middle insulators 110A and 110B, and the semiconductor layers 306A, 306B, 308A, 308B, 312A, 312B, 314A, 314B, 318A, 318B, 320A, and 320B.

After the selective etching process, the middle recesses 342A are formed in the positions previously hold by the semiconductor layers 316A, and the middle recesses 342B are formed in the positions previously hold by the semiconductor layers 316B. That is, the middle recesses 342A are formed between the topmost semiconductor layers 312A and the semiconductor layers 318A, and the middle recesses 342B are formed between the topmost semiconductor layers 312B and the semiconductor layers 318B. The selective etching process may be a dry etching process, a wet etching process, other suitable etching process, or a combination thereof.

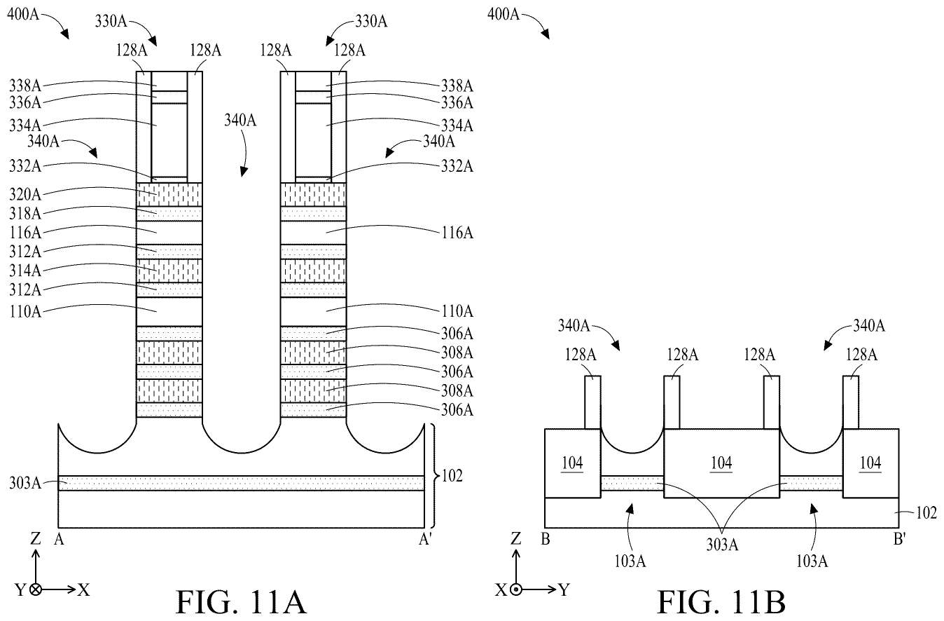

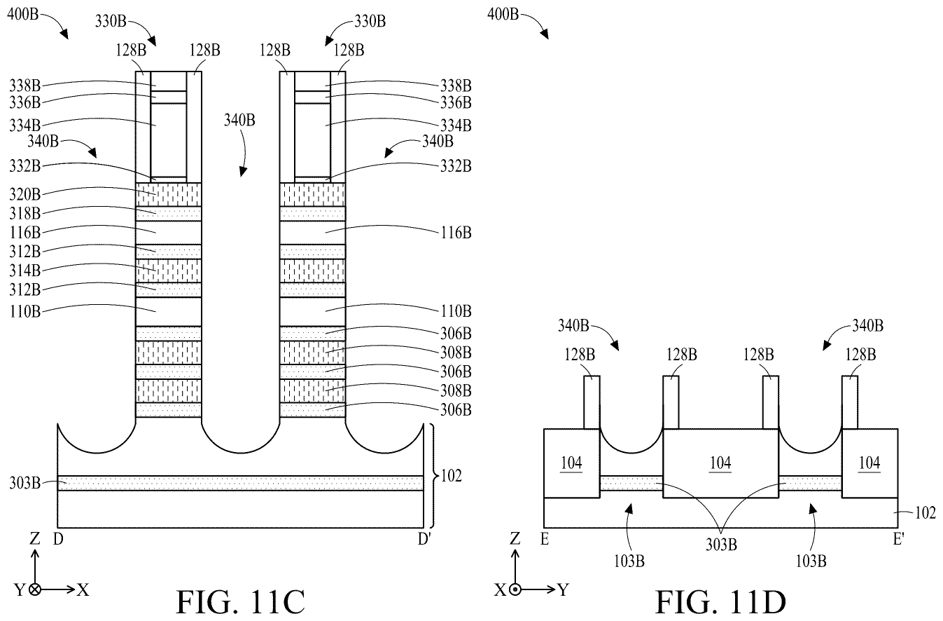

Referring to FIGS. 11A-11D, the ESLs 116A are formed in the middle recesses 342A and the ESLs 116B are formed in the middle recesses 342B, in accordance with some embodiments. In some embodiments, a deposition process is performed to form a dielectric material layer into the source/drain trenches 340A and 340B and the middle recesses 342A and 342B. For example, the deposition process may be CVD, PVD, ALD, HDPCVD, MOCVD, RPCVD, PECVD, LPCVD, ALCVD, APCVD, another suitable method, or a combination thereof. The dielectric material layer partially (or completely) fills the source/drain trenches 340A and 340B, and fully fills the middle recesses 342A and 342B. The deposition process is configured to ensure that the dielectric material layer fills the middle recesses 342A and 342B. Furthermore, the dielectric material layer is also conformally formed on the gate spacers 128A and 128B and the isolation structures 104.

The dielectric material layer may include a material that is different than the materials of the semiconductor layers 306A, 306B, 308A, 308B, 312A, 312B, 314A, 314B, 318A, 318B, 320A, and 320B and the gate spacers 128A and 128B, so as to achieve desired etching selectivity during the etching process. In some embodiments, the dielectric material layer includes a dielectric material that includes silicon, oxygen, carbon, nitrogen, other suitable materials, or combinations thereof (e.g., SiO₂, SiON, SiOC, SiCN, SiOCN). In some embodiments, the dielectric material layer includes a low-k dielectric material, such as those described herein.

Then, in some embodiments, an etching process is performed to selectively etch the dielectric material layer, so as to form the ESLs 116A in the middle recesses 342A and form the ESLs 116B in the middle recesses 342B, with minimal etching (or substantially no etching) of the substrate 102, the dummy gate structures 330A and 330B, the gate spacers 128A and 128B, and the semiconductor layers 306A, 306B, 308A, 308B, 312A, 312B, 314A, 314B, 318A, 318B, 320A, and 320B. The etching process may be an anisotropic etching process, removing the portions of the dielectric material layer that the dummy gate structures 330A and 330B and gate spacers 128A and 128B do not cover or vertically overlap. The portions of the dielectric material layer on the gate spacers 128A and 128B and the isolation structures 104 are also removed.

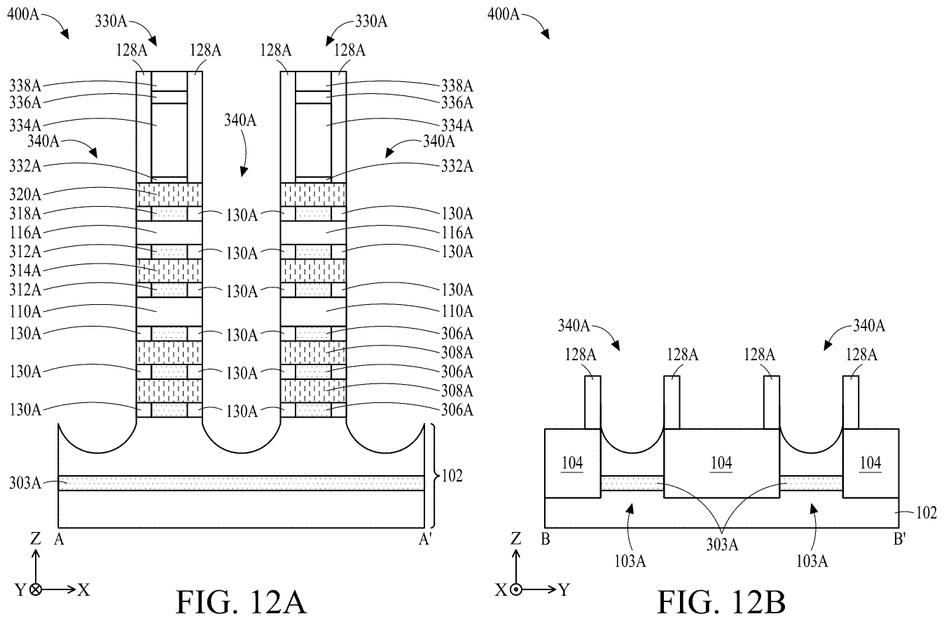

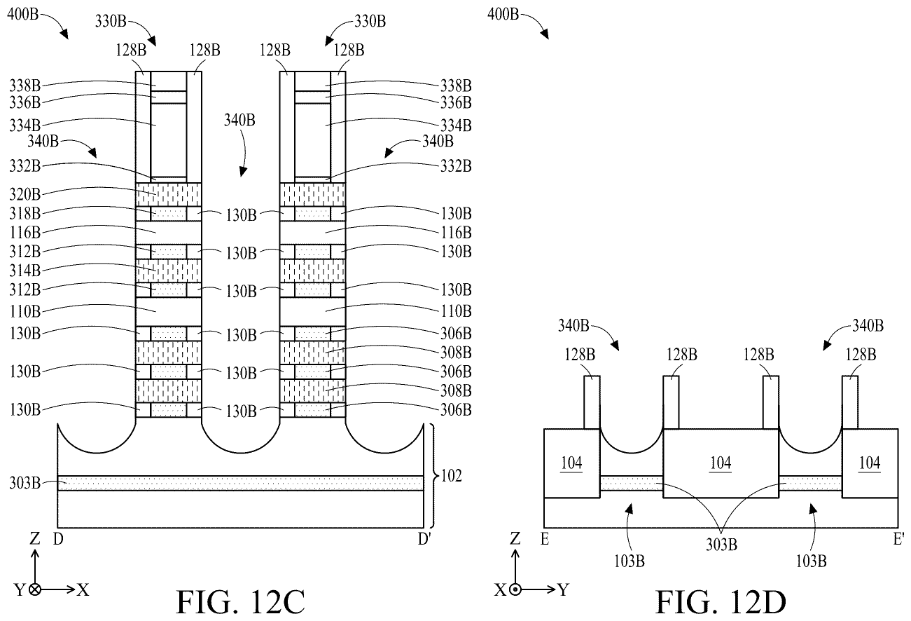

Referring to FIGS. 12A-12D, the inner spacers 130A and 130B are formed, in accordance with some embodiments. In some embodiments, the inner spacers 130A are formed between the semiconductor layers 308A and the substrate 102, between the semiconductor layers 308A, between the semiconductor layers 308A and the middle insulators 110A, between the middle insulators 110A and the semiconductor layers 314A, between the semiconductor layers 314A and the ESLs 116A, and between the ESLs 116A and the semiconductor layers 320A. In some embodiments, the inner spacers 130B are formed between the semiconductor layers 308B and the substrate 102, between the semiconductor layers 308B, between the semiconductor layers 308B and the middle insulators 110B, between the middle insulators 110B and the semiconductor layers 314B, between the semiconductor layers 314B and the ESLs 116B, and between the ESLs 116B and the semiconductor layers 320B.

In some embodiments, the semiconductor layers 306A, 306B, 312A, 312B, 318A, and 318B exposed in the source/drain trenches 340A and 340B are partially recessed through a selective etching process. More specifically, the selective etching process selectively etches side portions of the semiconductor layers 306A, 312A, and 318A below the gate spacers 128A through the source/drain trenches 340A, with minimal etching (or substantially no etching) of the substrate 102, the middle insulators 110A, the ESLs 116A, and the semiconductor layers 308A, 314A, and 320A. The selective etching process further selectively etches side portions of the semiconductor layers 306B, 312B, and 318B below the gate spacers 128B through the source/drain trenches 340B, with minimal etching (or substantially no etching) of the substrate 102, the middle insulators 110B, the ESLs 116B, and the semiconductor layers 308B, 314B, and 320B. The selective etching process may be a dry etching process, a wet etching process, other suitable etching process, or a combination thereof.

After the selective etching process, in the semiconductor structure 400A, inner spacer recesses are vertically formed below the gate spacers 128A, and vertically formed between the semiconductor layers 308A and the substrate 102, between the semiconductor layers 308A, between the semiconductor layers 308A and the middle insulators 110A, between the middle insulators 110A and the semiconductor layers 314A, between the semiconductor layers 314A and the ESLs 116A, and between the ESLs 116A and the semiconductor layers 320A. After the selective etching process, in the semiconductor structure 400B, inner spacer recesses are vertically formed below the gate spacers 128B, and vertically formed between the semiconductor layers 308B and the substrate 102, between the semiconductor layers 308B, between the semiconductor layers 308B and the middle insulators 110B, between the middle insulators 110B and the semiconductor layers 314B, between the semiconductor layers 314B and the ESLs 116B, and between the ESLs 116B and the semiconductor layers 320B.

Next, in some embodiments, a spacer layer is conformally formed into the source/drain trenches 340A and 340B and the inner spacer recesses. More specifically, a deposition process is performed to form the spacer layer into the source/drain trenches 340A and 340B and the inner spacer recesses, such as CVD, PVD, ALD, HDPCVD, MOCVD, RPCVD, PECVD, LPCVD, ALCVD, APCVD, FCVD, other suitable methods, or combinations thereof. The spacer layer partially (or completely) fills the source/drain trenches 340A and 340B and fully fills the inner spacer recesses. The deposition process is configured to ensure that the spacer layer fills the inner spacer recesses. Furthermore, the spacer layer is also conformally formed on the gate spacers 128A and 128B and the isolation structures 104.

The spacer layer may include a material that is different than the materials of the semiconductor layers 306A, 306B, 308A, 308B, 312A, 312B, 314A, 314B, 318A, 318B, 320A, and 320B and the gate spacers 128A and 128B, so as to achieve desired etching selectivity during the etching process. In some embodiments, the spacer layer includes a dielectric material that includes silicon, oxygen, carbon, nitrogen, other suitable materials, or combinations thereof (e.g., SiO₂, SiON, SiOC, SiCN, SiOCN). In some embodiments, the spacer layer includes a low-k dielectric material, such as those described herein.

Then, in some embodiments, the inner spacers 130A are formed to fill the inner spacer recesses in the semiconductor structure 400A, and the inner spacers 130B are formed to fill the inner spacer recesses in the semiconductor structure 400B. More specifically, an etching process is performed to selectively etch the spacer layer to form the inner spacers 130A and 130B, with minimal etching (or substantially no etching) of the substrate 102, the dummy gate structures 330A and 330B, the gate spacers 128A and 128B, and the semiconductor layers 306A, 306B, 308A, 308B, 312A, 312B, 314A, 314B, 318A, 318B, 320A, and 320B. The etching process may be an anisotropic etching process, removing the portions of the spacer layer that the dummy gate structures 330A and 330B and gate spacers 128A and 128B do not cover or vertically overlap. The portions of the spacer layer on the gate spacers 128A and 128B and the isolation structures 104 are also removed.

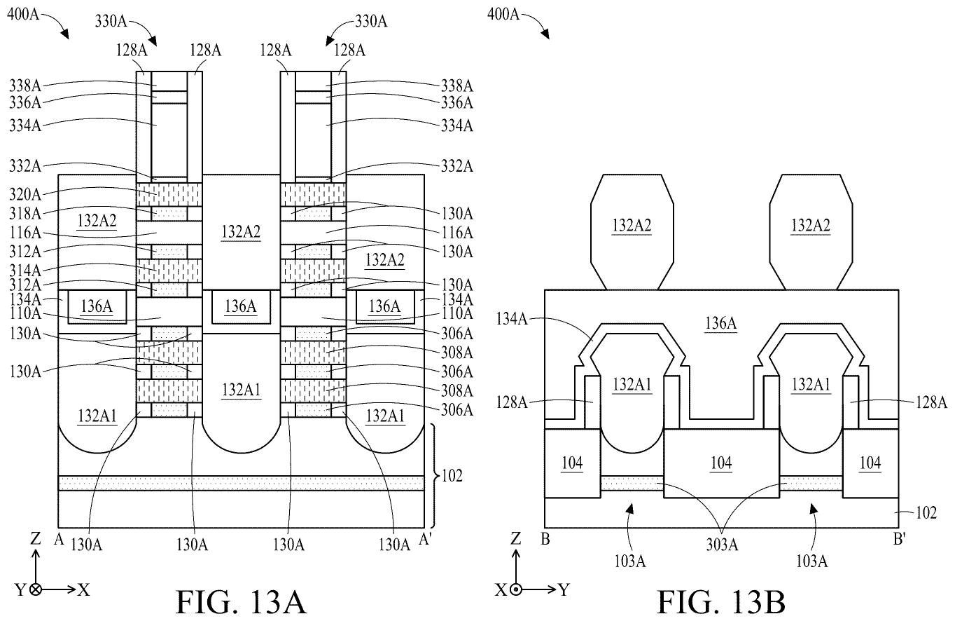

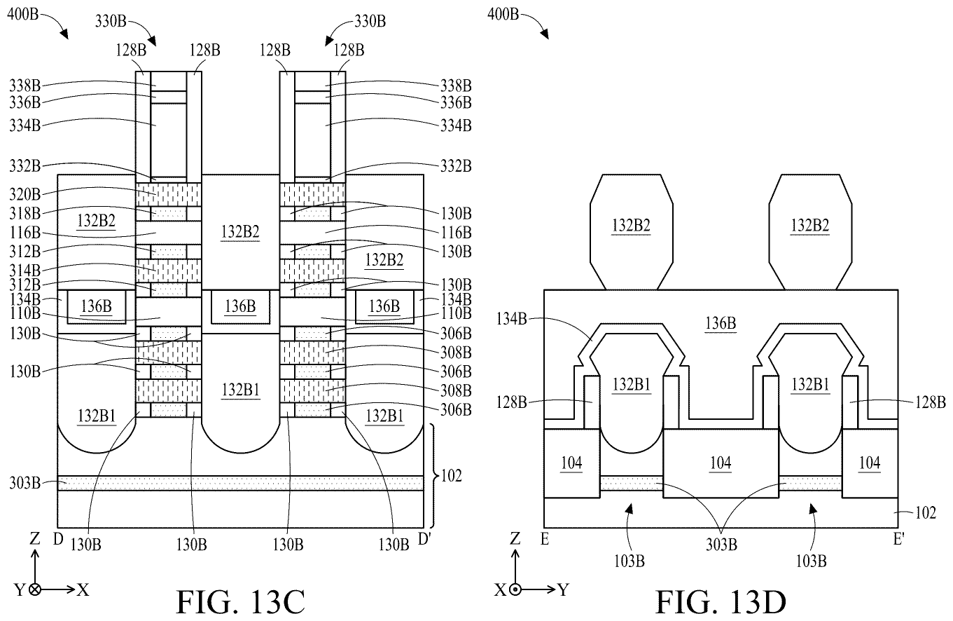

Referring to FIGS. 13A-13D, the source/drain features 132A1 are formed in the lower parts of the source/drain trenches 340A, and the source/drain features 132B1 are formed in the lower parts of the source/drain trenches 340B, in accordance with some embodiments. In some embodiments, dummy material layers are first formed in the lower parts of the source/drain trenches 340A and 340B, so as to cover the substrate 102, the sidewalls of the semiconductor layers 308A and 308B, and the sidewalls of the inner spacers 130A and 130B (which are lower than the middle insulators 110A and 110B). In some embodiments, the top surfaces of the dummy material layers are higher than the bottom surfaces of the middle insulators 110A and 110B.

After the formation of the dummy material layers, spacer material layers are conformally formed over the dummy material layers and formed on the sidewalls of the source/drain trenches 340A and 340B. More specifically, the spacer material layers are formed on the top surfaces of the dummy material layers, and formed on the sidewalls of the ESLs 116A and 116B, the semiconductor layers 314A, 314B, 320A, and 320B, the gate spacers 128A and 128B, and the inner spacers 130A and 130B (which are higher than the middle insulators 110A and 110B).

Then, in some embodiments, an anisotropic etching process is performed to remove horizontal portions of the spacer material layers to expose the top surfaces of the dummy material layers, and then a selective etching process is performed to remove the dummy material layers. In some embodiments, the vertical portions of the spacer material layers are partially removed or trimmed, and the remained vertical portions of the spacer material layers form the cover spacers. In some embodiments, the cover spacers cover the sidewalls of ESLs 116A and 116B, the semiconductor layers 314A, 314B, 320A, and 320B, the gate spacers 128A and 128B, and the inner spacers 130A and 130B (which are higher than the middle insulators 110A and 110B). In some embodiments, the cover spacers further partially cover the sidewalls of the middle insulators 110A and 110B. The selective etching process is performed that selectively etches the dummy material layers below the spacer material layers, with minimal etching (or substantially no etching) of other elements. The selective etching process may be a dry etching process, a wet etching process, other suitable etching process, or combinations thereof.

After the formation of the cover spacers, the source/drain features 132A1 and 132B1 are formed, in accordance with some embodiments. In some embodiments, the source/drain features 132A1 are formed in the lower parts of the source/drain trenches 340A, below the cover spacers, on the substrate 102, and on opposite sides of the dummy gate structure 330A in the X-direction, as shown in FIG. 13A. In some embodiments, the source/drain features 132A1 are attached to opposite sides of the semiconductor layers 308A, and electrically connected to the semiconductor layers 308A. In some embodiments, the source/drain features 132A1 may have the top surfaces that extend higher than top surfaces of the topmost semiconductor layers 308A (e.g., in the Z-direction). In some embodiments, the top surfaces of the source/drain features 132A1 are lower than the middle insulators 110A. In other embodiments, the top surfaces of the source/drain features 132A1 are higher than the bottom surfaces of the middle insulators 110A.

In some embodiments, the source/drain features 132B1 are formed in the lower parts of the source/drain trenches 340B, below the cover spacers, on the substrate 102, and on opposite sides of the dummy gate structure 330B in the X-direction, as shown in FIG. 13C. In some embodiments, the source/drain features 132B1 are attached to opposite sides of the semiconductor layers 308B, and electrically connected to the semiconductor layers 308B. In some embodiments, the source/drain features 132B1 may have the top surfaces that extend higher than top surfaces of the topmost semiconductor layers 308B (e.g., in the Z-direction). In some embodiments, the top surfaces of the source/drain features 132B1 are lower than the middle insulators 110B. In other embodiments, the top surfaces of the source/drain features 132B1 are higher than the bottom surfaces of the middle insulators 110B.

In some embodiments, the source/drain features 132A1 and 132B1 are formed by using an epitaxial growth process such as VPE, MOCVD, MBE, although other deposition processes, such as CVD, LPCVD, PECVD, ALD, UHVCVD, RPCVD, a combination thereof, or the like, may also be utilized. In some embodiments, the source/drain features 132A1 are grown from the substrate 102 and the end portions of the semiconductor layers 308A, and the source/drain features 132B1 are grown from the substrate 102 and the end portions of the semiconductor layers 308B. The source/drain features 132A1 and 132B1 are grown from the semiconductor layers 308A and 308B rather than the semiconductor layers 314A, 314B, 320A, and 320B, it is because that the cover spacers cover the sidewalls of the semiconductor layers 314A, 314B, 320A, and 320B.

In some embodiments, the semiconductor structure 400A may further include the undoped epitaxial layers formed on the substrate 102 and below the source/drain features 132A1. Similarly, the semiconductor structure 400B may further include the undoped epitaxial layers formed on the substrate 102 and below the source/drain features 132B1. The undoped epitaxial layers may include a semiconductor material (e.g., Si, Ge, or SiGe) that is substantially free of n-type and p-type dopants, and may be epitaxially grown using an epitaxial growth process.

In some embodiments, the semiconductor structure 400A may further include the bottom isolation layers that are formed between the source/drain features 132A1 and the undoped epitaxial layers, or formed between the source/drain features 132A1 and the substrate 102. Similarly, the semiconductor structure 400B may further include bottom isolation layers that are formed between the source/drain features 132B1 and the undoped epitaxial layers, or formed between the source/drain features 132B1 and the substrate 102. In some embodiments, the bottom isolation layers include a dielectric material, and are formed by a deposition process.

After the formation of the source/drain features 132A1 and 132B1, the cover spacers may be removed through a selective etching process. In some embodiments, the selective etching process is performed that selectively etches the cover spacers, with minimal etching (or substantially no etching) of other elements. The selective etching process may be a dry etching process, a wet etching process, other suitable etching process, or combinations thereof.

Still referring to FIGS. 13A-13D, after forming the source/drain features 132A1 and 132B1, the CESLs 134A and the ILD layers 136A are formed on the source/drain features 132A1, and the CESLs 134B and the ILD layers 136B are formed on the source/drain features 132B1, in accordance with some embodiments. In some embodiments, the CESLs 134A are first conformally formed on the top surfaces of the source/drain features 132A1 and the isolation structures 104, and formed on sidewalls of the source/drain trenches 340A, the source/drain features 132A1, and the gate spacers 128A. Similarly, the CESLs 134B may be first conformally formed on the top surfaces of the source/drain features 132B1 and the isolation structures 104, and formed on sidewalls of the source/drain trenches 340B, the source/drain features 132B1, and the gate spacers 128B.

In some embodiments, the CESLs 134A and 134B may include La₂O₃, Al₂O₃, SiOCN, SiOC, SiCN, SiO₂, SiC, ZnO, ZrN, Zr₂Al₃O₉, TiO₂, TaO₂, ZrO₂, HfO₂, Si₃N₄, Y₂O₃, AlON, TaCN, ZrSi, or other suitable materials. The CESLs 134A and 134B may be formed by CVD, PVD, ALD, HDPCVD, MOCVD, RPCVD, PECVD, LPCVD, ALCVD, APCVD, FCVD, or other suitable methods.

Then, in some embodiments, the ILD layers 136A are formed over and between the CESLs 134A to fill the spaces between the CESLs 134A, and the ILD layers 136B are formed over and between the CESLs 134B to fill the spaces between the CESLs 134B. The ILD layers 136A and 136B may include materials that are different than the CESLs 134A and 134B. In some embodiments, the ILD layers 136A and 136B include TEOS formed oxide, un-doped silicate glass, or doped silicon oxide such as borophosphosilicate glass (BPSG), FSG, phosphosilicate glass (PSG), boron silicate glass (BSG), low-k dielectric materials, other suitable dielectric materials, or combinations thereof. The ILD layers 136A and 136B may be formed by CVD, PVD, ALD, HDPCVD, MOCVD, RPCVD, PECVD, LPCVD, ALCVD, APCVD, FCVD, or other suitable methods.

After forming the CESLs 134A and 134B and the ILD layers 136A and 136B, an etching back process may be performed to reduce heights of the CESLs 134A and 134B and the ILD layers 136A and 136B. After the etching back process, the heights of the CESLs 134A and 134B and the ILD layers 136A and 136B are reduced, and thus the spaces of the source/drain trenches 340A and 340B for forming the source/drain features 132A2 and 132B2 are provided.

Still referring to FIGS. 13A-13D, the source/drain features 132A2 and 132B2 are formed, in accordance with some embodiments. In some embodiments, the source/drain features 132A2 are formed in the source/drain trenches 340A, over the CESLs 134A and the ILD layers 136A, and on opposite sides of the dummy gate structure 330A in the X-direction. In some embodiments, the source/drain features 132A2 may be spaced apart from the source/drain features 132A1 by the CESLs 134A and the ILD layers 136A in the Z-direction. In some embodiments, the source/drain features 132A2 are attached to opposite sides of the semiconductor layers 314A and 320A, and electrically connected to the semiconductor layers 314A and 320A. In some embodiments, the source/drain features 132A2 may have the top surfaces that are higher than top surfaces of the semiconductor layers 320A (e.g., in the Z-direction). In some embodiments, the top surfaces of the source/drain features 132A2 are higher than the middle insulators 110A. In other embodiments, the top surfaces of the source/drain features 132A2 are lower than the top surfaces of the middle insulators 110A.

In some embodiments, the source/drain features 132B2 are formed in the source/drain trenches 340B, over the CESLs 134B and the ILD layers 136B, and on opposite sides of the dummy gate structure 330B in the X-direction. The source/drain features 132B2 may be spaced apart from the source/drain features 132B1 by the CESLs 134B and the ILD layers 136B in the Z-direction. In some embodiments, the source/drain features 132B2 are attached to opposite sides of the semiconductor layers 314B and 320B, and electrically connected to the semiconductor layers 314B and 320B. In some embodiments, the source/drain features 132B2 may have the top surfaces that are higher than top surfaces of the semiconductor layers 320B (e.g., in the Z-direction). In some embodiments, the top surfaces of the source/drain features 132B2 are higher than the middle insulators 110B. In other embodiments, the top surfaces of the source/drain features 132B2 are lower than the top surfaces of the middle insulators 110B.

In some embodiments, the source/drain features 132A2 and 132B2 may be formed by using epitaxial growth process such as VPE, MOCVD, MBE, although other deposition processes, such as CVD, LPCVD, PECVD, ALD, UHVCVD, RPCVD, a combination thereof, or the like, may also be utilized. In some embodiments, the source/drain features 132A2 are grown from the end portions of the semiconductor layers 314A and 320A, and the source/drain features 132B2 are grown from the end portions of the semiconductor layers 314B and 320B. The source/drain features 132A2 and 132B2 are grown from the semiconductor layers 314A, 314B, 320A, and 320B rather than the source/drain features 132A1 and 132B1, it is because that the CESLs 134A and the ILD layers 136A cover the source/drain features 132A1 and the CESLs 134B and the ILD layers 136B cover the source/drain features 132B1.

In some embodiments, the source/drain features 132A1 and 132B1 are p-type source/drain features used for PFETs and the source/drain features 132A2 and 132B2 are n-type source/drain features used for NFETs. Alternatively, the source/drain features 132A1 and 132B1 may be n-type source/drain features used for NFETs and the source/drain features 132A2 and 132B2 may be p-type source/drain features used for PFETs.

The p-type source/drain features may include epitaxially-grown material selected from a group consisting of boron-doped SiGe, boron-doped SiGeC, boron-doped Ge, boron-doped Si, boron and carbon doped SiGe, or a combination thereof. In some embodiments, the p-type source/drain features may be doped with p-type dopants and have a doping concentration greater than 5×10²⁰/cm³. The n-type source/drain features may include epitaxially-grown material selected from a group consisting of SiP, SiC, SiPC, SiAs, Si, or a combination thereof. In some embodiments, the n-type source/drain features are doped with n-type dopants and have a doping concentration greater than 1×10²¹/cm³. The source/drain features 132A1, 132B1 132A2, and 132B2 may be doped in-situ or ex-situ. One or more annealing processes may be performed to activate the dopants in the source/drain features 132A1, 132B1 132A2, and 132B2. The annealing processes may include rapid thermal annealing (RTA) and/or laser annealing processes.

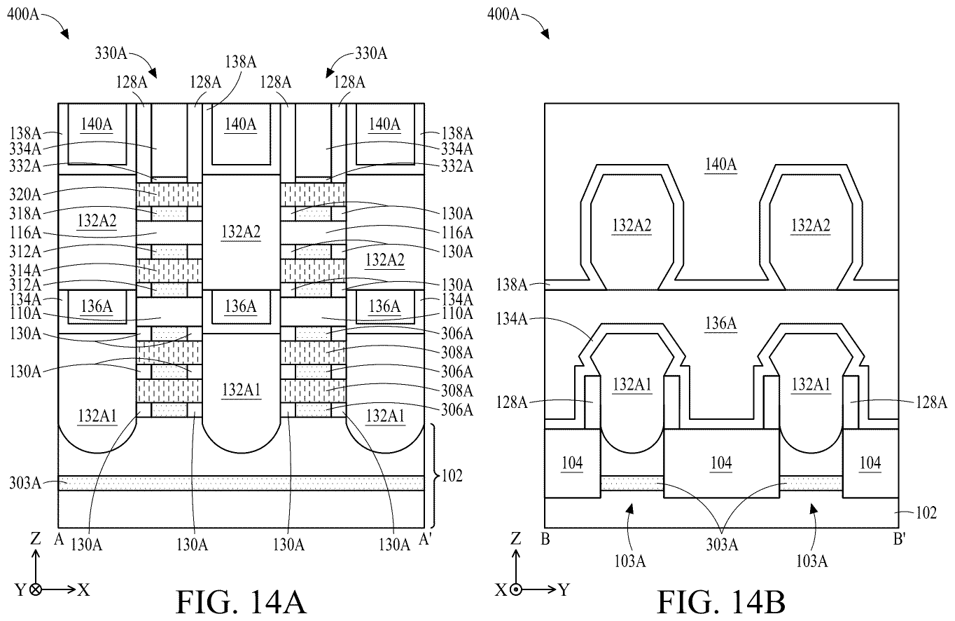

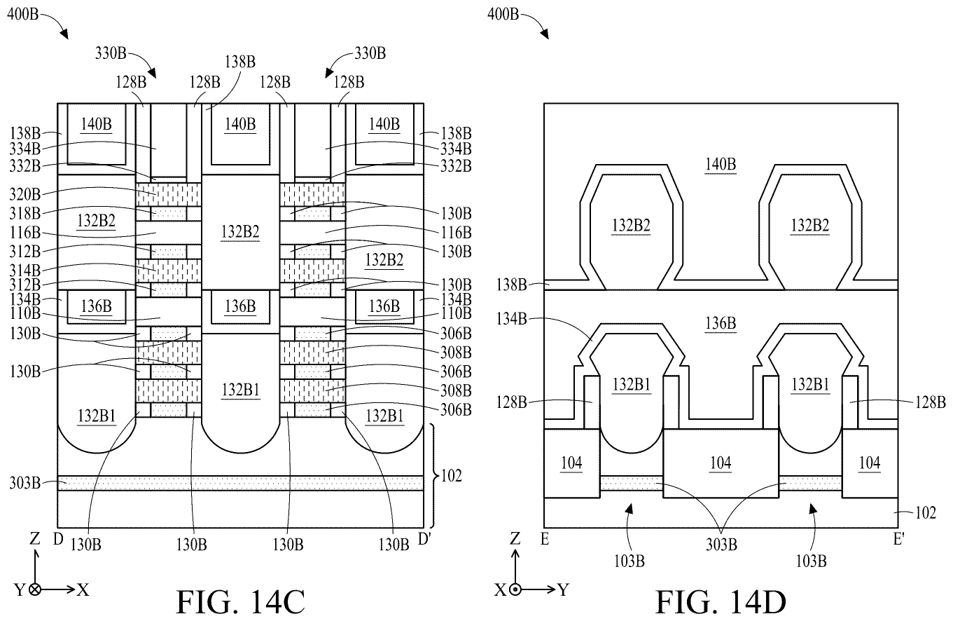

Referring to FIGS. 14A-14D, the CESLs 138A and the ILD layers 140A are formed on the source/drain features 132A2, and the CESLs 138B and the ILD layers 140B are formed on the source/drain features 132B2, in accordance with some embodiments. In some embodiments, the CESLs 138A are first conformally formed on the top surfaces of the source/drain features 132A2 and the ILD layers 136A, and formed on sidewalls of the source/drain features 132A2 and the gate spacers 128A. Similarly, the CESLs 138B may be first conformally formed on the top surfaces of the source/drain features 132B2 and the ILD layers 136B, and formed on sidewalls of the source/drain features 132B2 and the gate spacers 128B. In some embodiments, the method and material used in forming the CESLs 138A and 138B are the same as or similar to those of the CESLs 134A and 134B, and are not repeated herein.

Then, in some embodiments, the ILD layers 140A are formed over and between the CESLs 138A to fill the spaces between the CESLs 138A, and the ILD layers 140B are formed over and between the CESLs 138B to fill the spaces between the CESLs 138B. The ILD layers 140A and 140B may include materials that are different than the CESLs 138A and 138B. In some embodiments, the method and material used in forming the ILD layers 140A and 140B are the same as or similar to those of the ILD layers 136A and 136B, and are not repeated herein. Afterward, in some embodiments, a CMP process is performed to reduce heights of the CESLs 138A and 138B and the ILD layers 140A and 140B, until top surfaces of the dummy gate electrode layers 334A of the dummy gate structures 330A and top surfaces of the dummy gate electrode layers 334B of the dummy gate structures 330B are exposed.

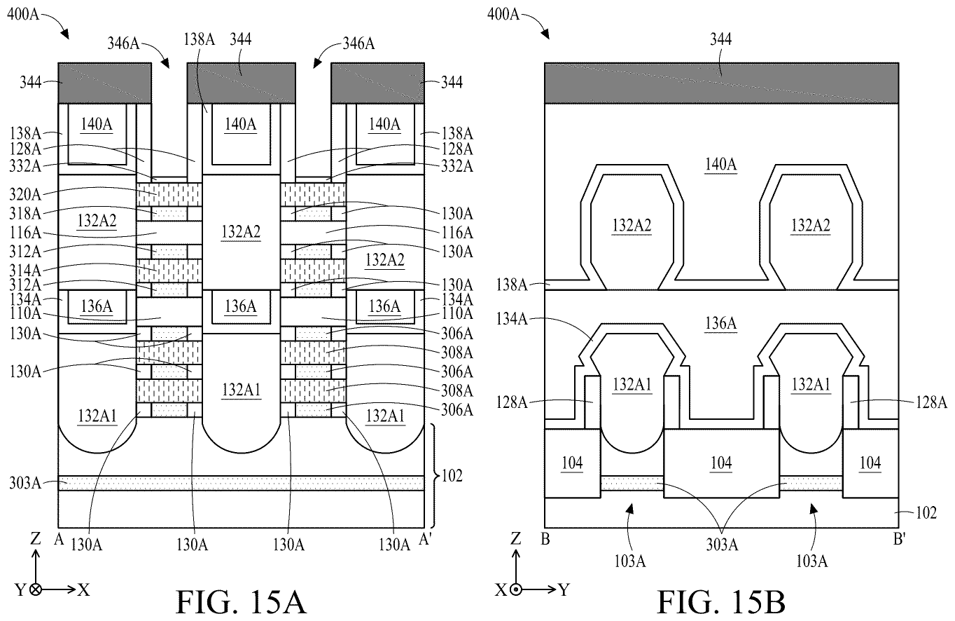

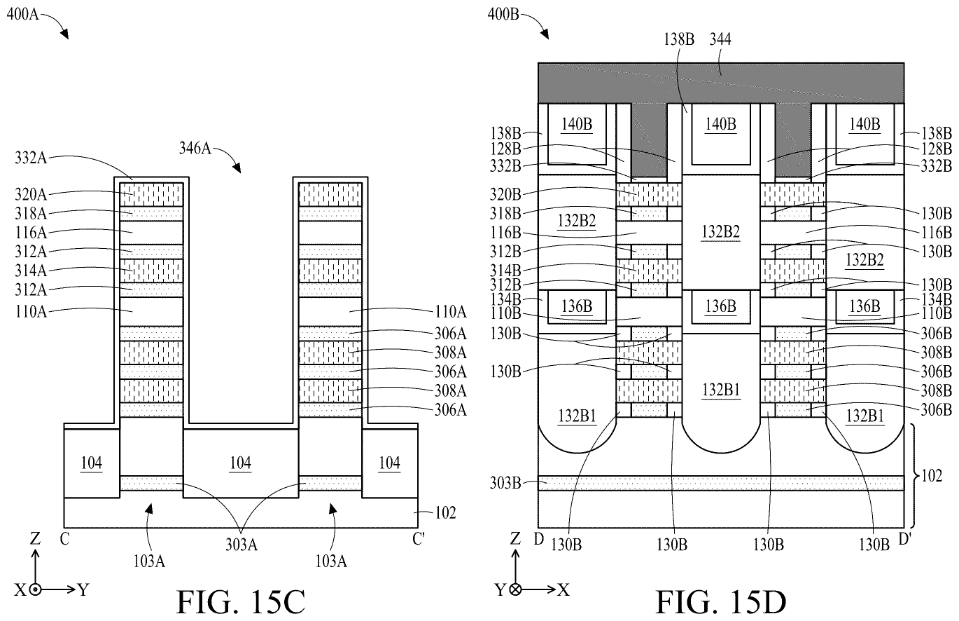

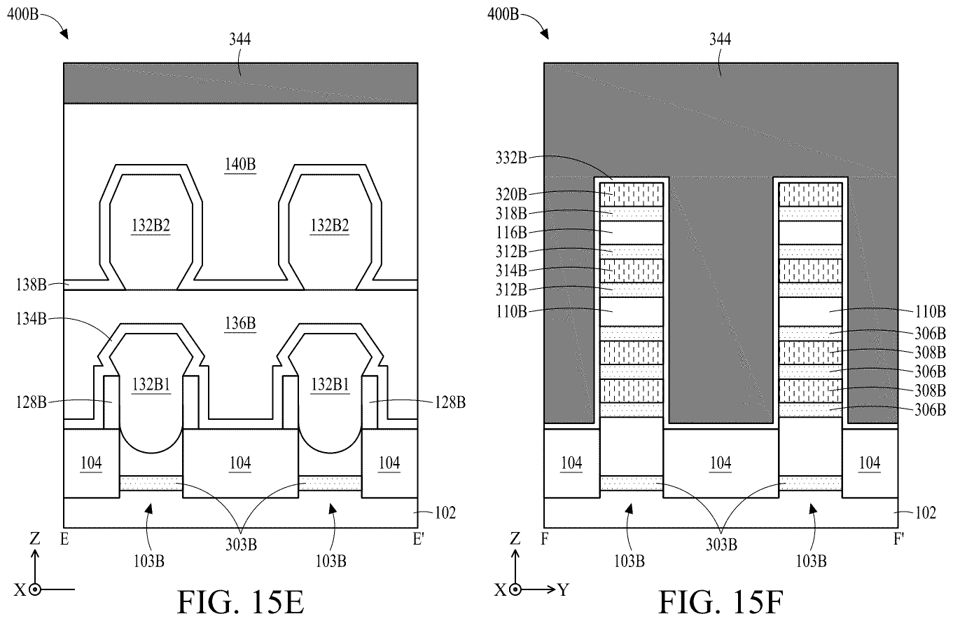

Referring to FIGS. 15A-15F, the dummy gate electrode layers 334A and 334B of the dummy gate structures 330A and 330B are removed through a selective etching process, in accordance with some embodiments. More specifically, the selective etching process is performed that selectively etches the dummy gate electrode layers 334A and 334B, with minimal etching (or substantially no etching) of the dummy gate dielectric layers 332A and 332B, the gate spacers 128A and 128B, the CESLs 138A and 138B, and the ILD layers 140A and 140B. After the selective etching process, the dummy gate dielectric layers 332A and 332B are exposed.

Still referring to FIGS. 15A-15F, a mask layer 344 is formed over the semiconductor structures 400A and 400B, in accordance with some embodiments. More specifically, the mask layer 344 is patterned to form gate trenches 346A that expose the dummy gate dielectric layers 332A of the dummy gate structures 330A, while other elements of the workpiece 300 are still covered by the mask layer 344. For example, the mask layer 344 covers the dummy gate dielectric layers 332B, the gate spacers 128A and 128B, the CESLs 138A and 138B, and the ILD layers 140A and 140B, as shown in FIGS. 15A-15F. In some embodiments, the mask layer 344 includes photoresist or a dielectric material such as oxide and nitride.

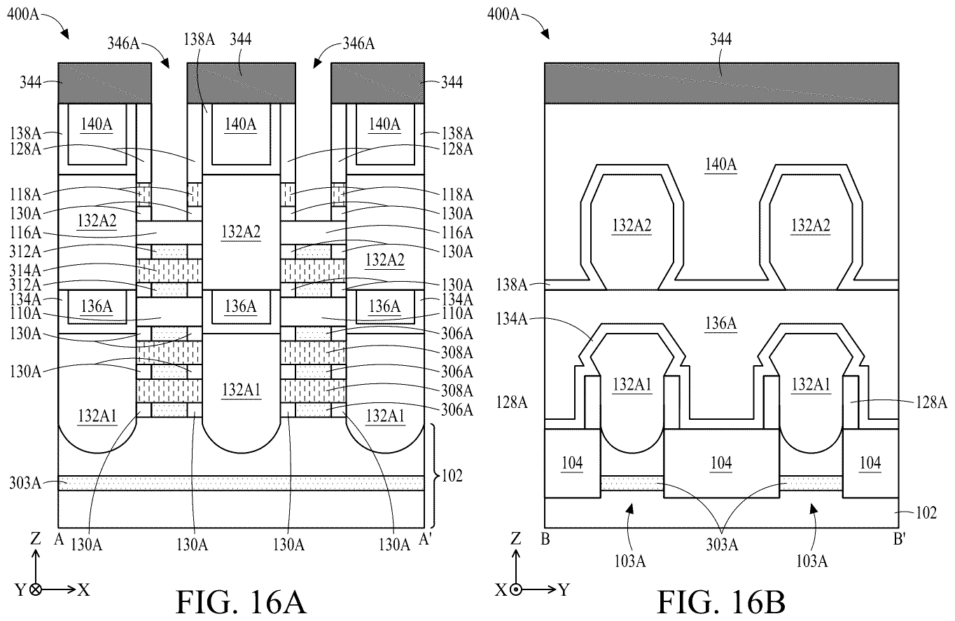

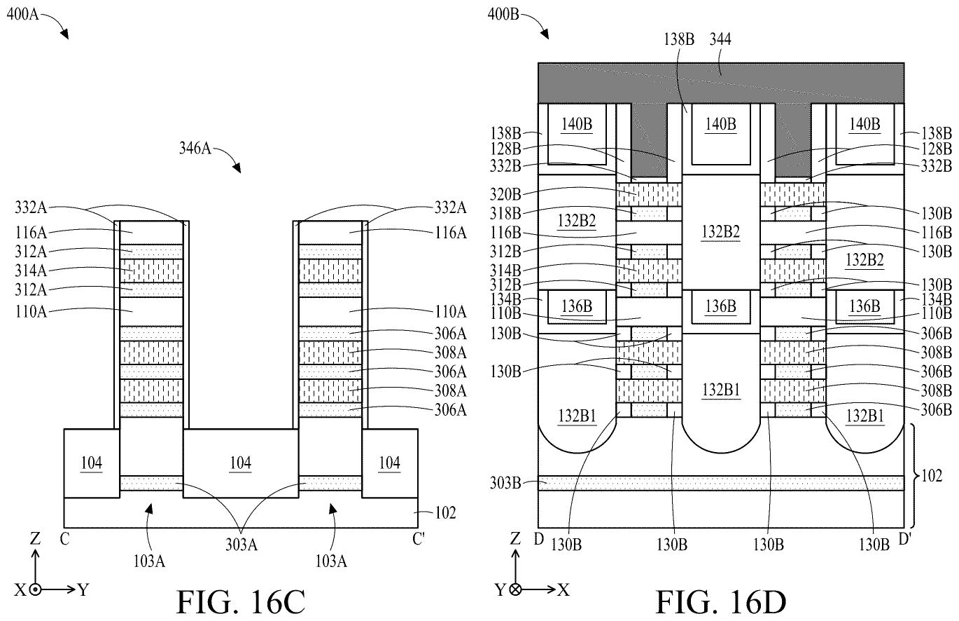

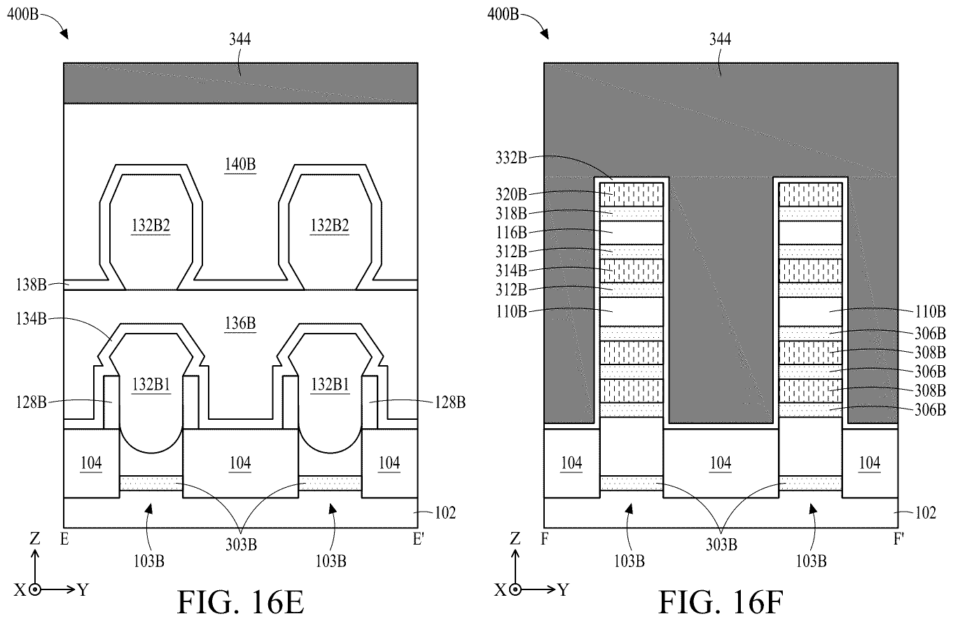

Referring to FIGS. 16A-16F, an etching process is performed to partially remove the dummy gate dielectric layers 332A and the semiconductor layers 320A, and remove the semiconductor layers 318A through the gate trenches 346A, in accordance with some embodiments. More specifically, the etching process may be an anisotropic etching process to remove horizontal portions of the dummy gate dielectric layers 332A exposed by the gate trenches 346A. The anisotropic etching process may further remove portions of the semiconductor layers 320A exposed by the gate trenches 346A, while portions of the semiconductor layers 320A covered by the gate spacers 128A are remained. The remaining portions of the semiconductor layers 320A may form the semiconductor segments 118A. In some embodiments, the semiconductor segments 118A are between the gate spacers 128A and the inner spacers 130A that are formed over the ESLs 116A, and thus between the gate spacers 128A and the middle insulators 110A, as shown in FIG. 16A.

In some embodiments, the anisotropic etching process may further remove the semiconductor layers 318A to extend the gate trenches 346A until the ESLs 116A are exposed. In some embodiments, the ESLs 116A function as etch stop layers during the anisotropic etching process. After the anisotropic etching process, the gate spacers 128A, the semiconductor segments 118A, the inner spacers 130A formed over the ESLs 116A, and the ESLs 116A are exposed in the gate trenches 346A. In some embodiments, the anisotropic etching process is a dry etching process.

As described above, by way of bonding two initial epitaxial structures (e.g., the first epitaxial structure 300A and the second epitaxial structure 300B), a budget of critical thickness can be released to form an additional SiGe layer with high Ge concentration (e.g., the semiconductor layer 316), which can be replaced by etch stop layers (e.g., the ESLs 116A and 116B). As shown in FIGS. 16A-16F, the ESLs 116A may function as etch stop layers during the removal of the semiconductor layers 320A. In this way, the semiconductor layers 320A can be removed during the fabrication process that is performed after the initial epitaxial structure has been defined. Since the semiconductor layers 320A are removed, the resultant semiconductor structure 400A may have less channels (i.e., nanostructures) than the resultant semiconductor structure 400B. That is, with the assistance of the ESLs 116A and 116B, the number of channels of the semiconductor structures can be modified during the fabrication process. As a result, the embodiments described herein can provide the flexibility for modifying the number of channels to modify the device performance.

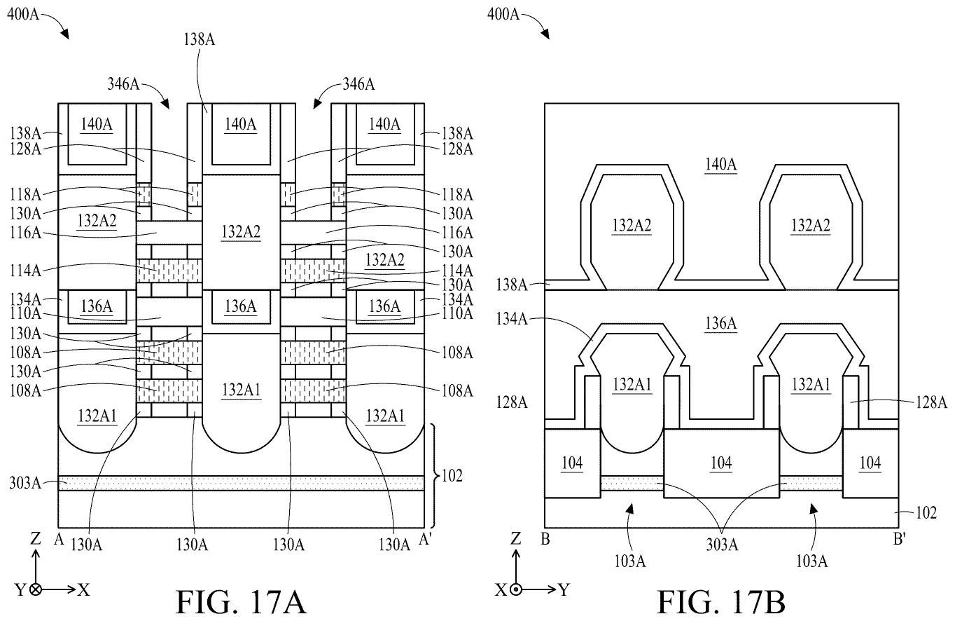

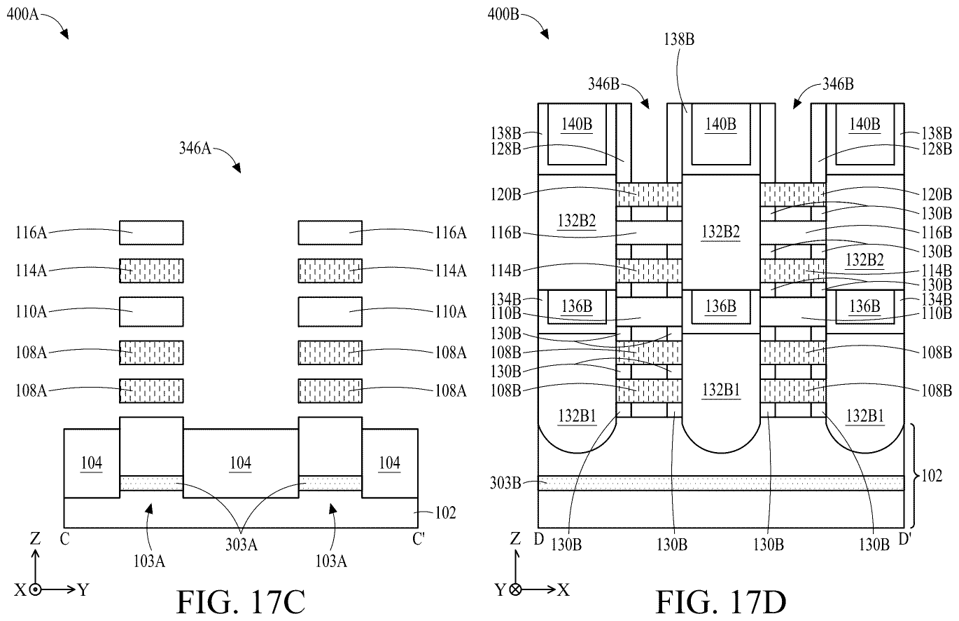

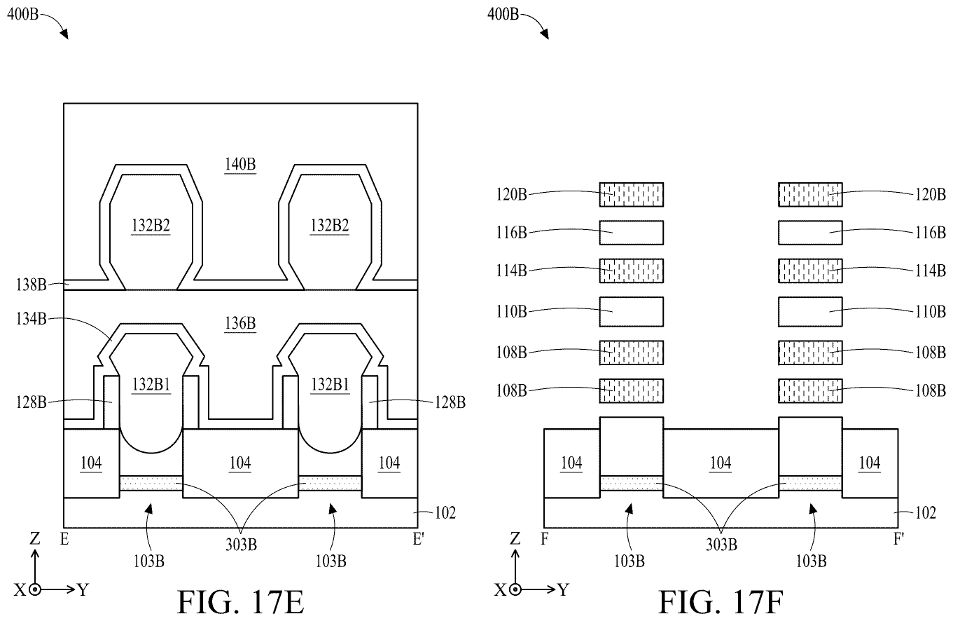

Referring to FIGS. 17A-17F, the mask layer 344 is removed, then, the dummy gate dielectric layers 332B and the remaining portions of the dummy gate dielectric layers 332A are selectively removed by any suitable photolithography and etching processes, in accordance with some embodiments. In some embodiments, the photolithography process may include forming a photoresist layer, exposing the photoresist to a pattern, performing a post-exposure bake process, and developing the photoresist to form a masking element, which exposes the regions including the gate trenches 346A and the dummy gate dielectric layers 332B. Then, the dummy gate dielectric layers 332B and the remaining portions of the dummy gate dielectric layers 332A are selectively etched through the masking element. The gate spacers 128A and 128B may be used as the masking element or a part thereof. Etch selectivity may be achieved by selecting appropriate etching chemicals, and the dummy gate dielectric layers 332A and 332B may be removed without substantially affecting the CESLs 138A and 138B and the ILD layers 140A and 140B. The removal of the remaining portions of the dummy gate dielectric layers 332A extends the gate trenches 346A, and the removal of the dummy gate dielectric layers 332B creates gate trenches 346B. The gate trenches 346A expose the top surfaces of the ESLs 116A. The gate trenches 346B expose the top surfaces of the semiconductor layers 320B that underlie the dummy gate dielectric layers 332B.

Still referring to FIGS. 17A-17F, an etching process is performed to extend the gate trenches 346A and 346B, in accordance with some embodiments. Specifically, the semiconductor layers 306A and 312A are selectively removed through the gate trenches 346A to extend the gate trenches 346A. Similarly, the semiconductor layers 306B, 312B, and 318B are selectively removed through the gate trenches 346B to extend the gate trenches 346B. In some embodiments, the etching process may be a wet or dry etching process.

After the semiconductor layers 306A and 312A are selectively removed, the semiconductor layers 308A and 314A are exposed in the gate trenches 346A to form the nanostructures 108A and 114A, respectively. After the semiconductor layers 306B, 312B, and 318B are selectively removed, the semiconductor layers 308B, 314B, and 320B are exposed in the gate trenches 346B to form the nanostructures 108B, 114B, and 120B, respectively. Such a process may be referred to as a wire/nanowire/nanosheet release process, or a wire/nanowire/nanosheet formation process. The configurations of the nanostructures 108A, 108B, 114A, 114B, and 120B have been discussed above, and are not repeated herein.

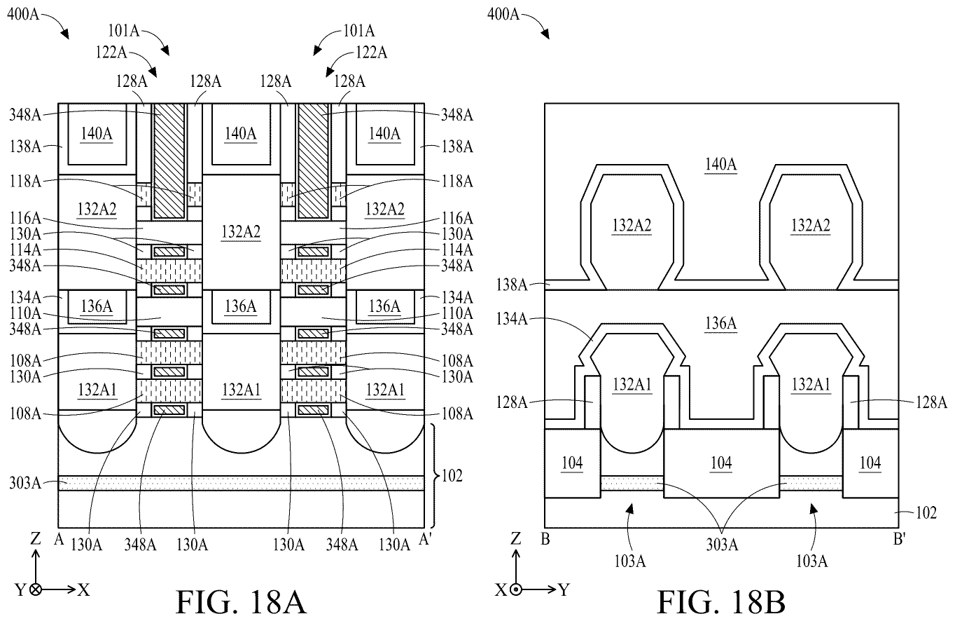

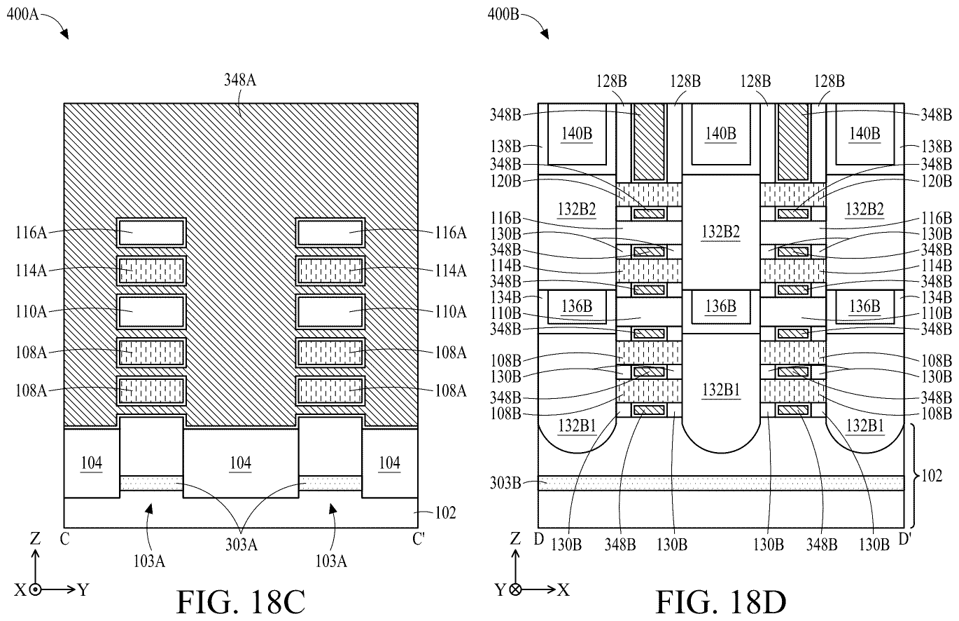

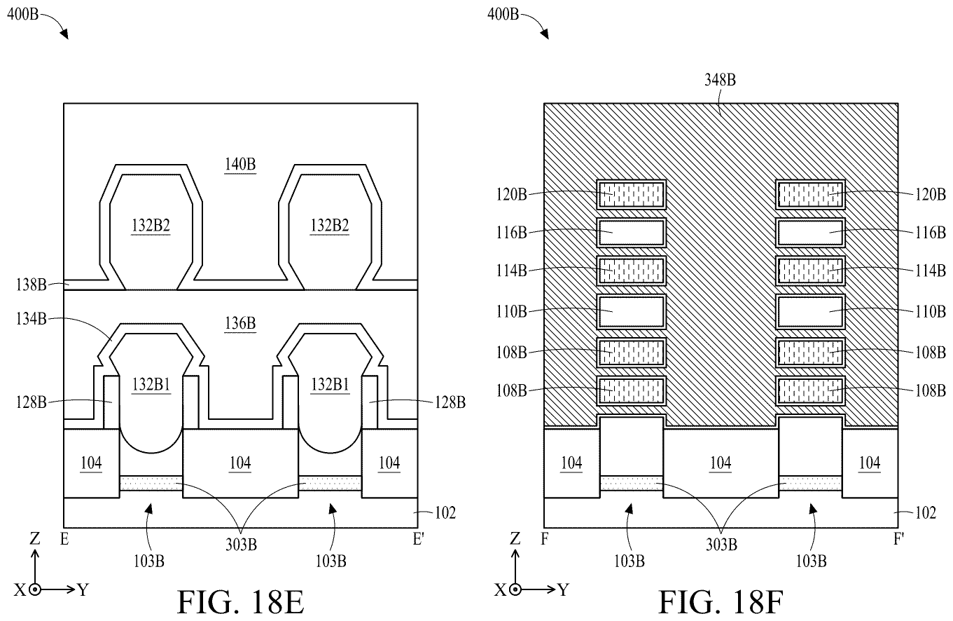

Referring to FIGS. 18A-18F, the gate dielectric layers 124A and gate materials 348A for the gate electrode layers 126A1 are formed in the gate trenches 346A, and the gate dielectric layers 124B and gate materials 348B for the gate electrode layers 126B1 are formed in the gate trenches 346A, in accordance with some embodiments. In some embodiments, the gate dielectric layers 124A are wrapped around each of the ESLs 116A, the middle insulators 110A, and the nanostructures 108A and 114A. In some embodiments, the gate materials 348A of the gate electrode layers 126A1 are wrapped around the gate dielectric layers 124A and each of the ESLs 116A, the middle insulators 110A, and the nanostructures 108A and 114A. Additionally, the gate dielectric layers 124A are also formed on the sidewalls of the inner spacers 130A, the gate spacers 128A, and the semiconductor segments 118A, as well as over the top surfaces of the substrate 102 and the isolation structures 104.

In some embodiments, the gate dielectric layers 124B are wrapped around each of the ESLs 116B, the middle insulators 110B, and the nanostructures 108B, 114B, and 120B. In some embodiments, the gate materials 348B of the gate electrode layers 126B1 are wrapped around the gate dielectric layers 124B and each of the ESLs 116B, the middle insulators 110B, and the nanostructures 108B, 114B, and 120B. In addition, the gate dielectric layers 124B are also formed on the sidewalls of the inner spacers 130B and the gate spacers 128B, as well as over the top surfaces of the substrate 102 and the isolation structures 104.

Referring back to FIGS. 1A-1F, the gate materials 348A and 248B are etched back to form the gate electrode layers 126A1 and 126B1, and then the gate electrode layers 126A2 and 126B2 are formed on the gate electrode layers 126A1 and 126B1, respectively, in accordance with some embodiments. In these embodiments, the resultant device of the workpiece 300 may be fabricated to as the semiconductor structure 100 shown in FIGS. 1A-1F. More specifically, the semiconductor structure 400A and 400B may be fabricated to as the semiconductor structure 100A and 100B, respectively.

In some embodiments, portions of the gate materials 348A that are wrapped around the nanostructures 114A and the ESLs 116A are removed by one or more etching processes to form the gate electrode layers 126A1. Similarly, portions of the gate materials 348B that are wrapped around the nanostructures 114B and 120B and the ESLs 116B are removed by one or more etching processes to form the gate electrode layers 126B1. In some embodiments, the etching processes may be selective etching processes that selectively etch the gate materials 348A and 348B, with minimal etching (or substantially no etching) of the gate dielectric layers 124A and 124B. The selective etching process may be a dry etching process, a wet etching process, other suitable etching process, or combinations thereof. In some embodiments, after the etching processes, the top surfaces of the gate electrode layers 126A1 and 126B1 are lower than the bottommost surfaces of the nanostructures 114A and 114B, respectively. In further embodiments, after the etching processes, the top surfaces of the gate electrode layers 126A1 and 126B1 are lower than the top surfaces of the middle insulators 110A and 110B, respectively.

Then, in some embodiments, gate materials for the gate electrode layers 126A2 are formed in the gate trenches 346A to form the gate electrode layers 126A2 on the gate electrode layers 126A1, and gate materials for the gate electrode layers 126B2 are formed in the gate trenches 346B to form the gate electrode layers 126B2 on the gate electrode layers 126B1. The gate electrode layers 126A2 may be formed over and wrapped around the gate dielectric layers 124A, and are wrapped around the ESLs 116A and the nanostructures 114A. The gate electrode layers 126B2 may be formed over and wrapped around the gate dielectric layers 124B, and are wrapped around the ESLs 116B and the nanostructures 114B and 120B.

As described above, the gate electrode layers 126A1 may be wrapped around portions of the gate dielectric layers 124A that are wrapped around the nanostructures 108A, so as to form the first gate structure used for the lower devices 101A1 of the CFETs 101A. The gate electrode layers 126A2 may be wrapped around portions of the gate dielectric layers 124A that are wrapped around the nanostructures 114A, so as to form a second gate structure used for the upper devices 101A2 of the CFETs 101A. The first gate structures and the second gate structures constitute the gate structures 122A, and the gate structures 122A replace the dummy gate structures 330A.

As described above, the gate electrode layers 126B1 may be wrapped around portions of the gate dielectric layers 124B that are wrapped around the nanostructures 108B, so as to form the first gate structure used for the lower devices 101B1 of the CFETs 101B. The gate electrode layers 126B2 may be wrapped around portions of the gate dielectric layers 124B that are wrapped around the nanostructures 114B and 120B, so as to form a second gate structure used for the upper devices 101B2 of the CFETs 101B. The first gate structures and the second gate structures constitute the gate structures 122B, and the gate structures 122B replace the dummy gate structures 330B.

In further embodiments, the gate electrode layers 126A1 are also formed on portions of the gate dielectric layers 124A that on the lower portions of the middle insulators 110A, and the gate electrode layers 126A2 are also formed on portions of the gate dielectric layers 124A that on the upper portions of the middle insulators 110A. Similarly, the gate electrode layers 126B1 are also formed on portions of the gate dielectric layers 124B that on the lower portions of the middle insulators 110B, and the gate electrode layers 126B2 are also formed on portions of the gate dielectric layers 124B that on the upper portions of the middle insulators 110B.

In some embodiments, the gate structures 122A and 122B further includes interfacial layers (not shown) formed between the gate dielectric layers 124A and the nanostructures (e.g., nanostructures 108A and 114A) or between the gate dielectric layers 124B and the nanostructures (e.g., nanostructures 108B, 114B, and 120B). For example, the interfacial layers may include a dielectric material such as SiO₂, HfSiO, or SiON, and may be formed by chemical oxidation, thermal oxidation, CVD, PVD, ALD, HDPCVD, MOCVD, RPCVD, PECVD, LPCVD, ALCVD, APCVD, FCVD, and/or other suitable method.

In some embodiments, the gate dielectric layers 124A and 124B may include a dielectric material, such as SiOCN, SiOC, SiCN, SiO₂, SiN, SiC, or other suitable materials. In some embodiments, the gate dielectric layers 124A and 124B may include a high-k dielectric material that has a dielectric constant greater than a dielectric constant of SiO₂, which is approximately 3.9. For example, the gate dielectric layers 124A and 124B may include HfO₂, TiO₂, HfZrO, Ta₂O₃, HfSiO₄, ZrO₂, ZrSiO₂, LaO, AlO, ZrO, TiO, Ta₂O₅, Y₂O₃, SrTiO₃ (STO), BaTiO₃ (BTO), BaZrO, HfLaO, HfSiO, LaSiO, AlSiO, HfTaO, HfTiO, (Ba,Sr) TiO₃ (BST), Al₂O₃, Si₃N₄, SiON, other suitable materials, or combinations thereof. The gate dielectric layers 124A and 124B may be formed by chemical oxidation, thermal oxidation, CVD, PVD, ALD, HDPCVD, MOCVD, RPCVD, PECVD, LPCVD, ALCVD, APCVD, FCVD, other suitable methods, or combinations thereof.

The gate electrode layers 126A1, 126A2, 126B1, and 126B2 each may include a single layer structure or a multi-layer structure. In some embodiments, the gate electrode layers 126A1, 126A2, 126B1, and 126B2 each may include a capping layer, a barrier layer, work function metal layers, and a fill material. The gate electrode layers 126A1, 126A2, 126B1, and 126B2 may be formed using a deposition process such as CVD, PVD, ALD, HDPCVD, MOCVD, RPCVD, PECVD, LPCVD, ALCVD, APCVD, FCVD, or the like, although any suitable deposition process may be used.

In some embodiments, the capping layer and the barrier layer may include different materials, and may be formed of metallic materials such as TaN, Ti, TiAlN, TiAl, Pt, TaC, TaCN, TaSiN, Mn, Zr, TiN, Ru, Mo, WN, other metal oxides, metal nitrides, metal silicates, transition metal-oxides, transition metal-nitrides, transition metal-silicates, oxynitrides of metals, metal aluminates, zirconium silicate, zirconium aluminate, combinations of these, or the like.

For PFETs, the gate electrode layers may include p-type work function metal layers. For NFETs, the gate electrode layers may include n-type work function metal layers. The n-type and p-type work function metal layers may include conductive materials tuned to have a desired work function (e.g., an n-type work function or a p-type work function). In some embodiments, the n-type and p-type work function metal layers may include a material such as W, Al, Cu, TiN, Ti, TiAlN, TiAl, Pt, Ta, TaN, Co, Ni, TaC, TaCN, TaSiN, TaSi₂, NiSi₂, Mn, Zr, ZrSi₂, Ru, AlCu, Mo, MoSi₂, WN, other suitable work function materials, or combinations thereof. In some embodiments, the fill material may include a suitable conductive material, such as Al, W, and/or Cu.

Referring back to FIG. 2, the semiconductor structure 200 may also formed by the embodiments shown in FIGS. 3A-18F. Take the semiconductor structure 400B shown in FIG. 15D as an example, the mask layer 344 may be configured to expose a first one of the dummy gate dielectric layers 332B of a first one of the dummy gate structures 330B. Then, during the fabrication stage shown in FIGS. 16A-16F, the first one of the dummy gate dielectric layers 332B may be removed, and the semiconductor layers 320B and 318B under the first one of the dummy gate dielectric layers 332B may also be removed. Subsequently, after undergoing the fabrication stages discussed with reference to FIGS. 17A-18F and FIGS. 1A-1F, the semiconductor structure 400B may be fabricated to as the semiconductor structure 200. In these embodiments, the ESLs 116B, the middle insulators 110B, and the semiconductor layers 308B, 314B, and 320B under the first one of the dummy gate dielectric layers 332B may be fabricated to as the ESLs 116A, the middle insulators 110A, the nanostructures 108A and 114A, and the semiconductor segments 118A. In these embodiments, the configuration of the gate structure that replaces the first one of the dummy gate structures 330B may the same as or similar to those of the gate structures 122A. In these embodiments, the configurations of the source/drain features 232A1, 232B1, and 232C1 may the same as or similar to those of the source/drain features 132A1 or 132B1, and the configurations of the source/drain features 232A2, 232B2, and 232C2 may the same as or similar to those of the source/drain features 132A2 or 132B2.

The embodiments disclosed herein relate to semiconductor structures and their forming methods, and more particularly to structures and methods that include bonding two initial epitaxial structures together to release a budget of critical thickness for forming an additional SiGe layer with high Ge concentration, which can be replaced by etch stop layers. The etch stop layers may be used to assist the process for reducing the number of channels (nanostructures). With the assistance of the etch stop layers, the number of channels of CFET or FET devices can be modified during the fabrication process. As a result, the flexibility for modifying the number of channels and for modifying the device performance is provided. Moreover, the bonding layers of the two initial epitaxial structures are bonded together during the bonding process. After the bonding process, the bonding layers that were bonded may function as middle insulators, and thus the process for forming the middle insulator can be omitted.

In one exemplary aspect, the present disclosure is directed to a method of forming a semiconductor structure. The method includes forming a first epitaxial structure and a first bonding layer on the first epitaxial structure, forming a second epitaxial structure and a second bonding layer on the second epitaxial structure, bonding the first epitaxial structure and the second epitaxial structure to form a third epitaxial structure by bonding the first bonding layer with the second bonding layer, and patterning the third epitaxial structure to form a fin structure. The method further includes forming a dummy gate structure over the fin structure, etching the fin structure to form source/drain trenches on opposite sides of the dummy gate structure, and forming first source/drain features and second source/drain features over the first source/drain features in the source/drain trenches. The dummy gate structure includes a dummy gate dielectric layer and a dummy gate electrode layer on the dummy gate dielectric layer. The method further includes forming a first gate trench exposing the dummy gate dielectric layer of the dummy gate structure, performing an etching process to remove the dummy gate dielectric layer of the dummy gate structure and a topmost semiconductor layer of the fin structure through the first gate trench, and forming a gate structure in the first gate trench.

In another exemplary aspect, the present disclosure is directed to a method of forming a semiconductor structure. The method includes forming a first fin structure and a second fin structure each including a first stack, a middle insulator over the first stack, and a second stack over the middle insulator, forming a first dummy gate structure and a second dummy gate structure over the first fin structure and the second fin structure, respectively, and etching the first fin structure and the second fin structure, so as to form first source/drain trenches on opposite sides of the first dummy gate structure and form second source/drain trenches on opposite sides of the second dummy gate structure. The second stack includes first semiconductor layers and a second semiconductor layer alternately stacked, a third semiconductor layer over a topmost one of the first semiconductor layers, a fourth semiconductor layer over the third semiconductor layer, and a fifth semiconductor layer over the fourth semiconductor layer. The method further includes replacing the third semiconductor layers of the first fin structure and the second fin structure with etch stop layers, and removing the first dummy gate structure and the fifth semiconductor layer and the fourth semiconductor layer of the first fin structure, so as to expose the etch stop layer of the first fin structure. The method further includes removing the fourth semiconductor layer of the second fin structure, removing the first semiconductor layers of the first fin structure and the second fin structure, and forming a first gate structure and a second gate structure on the first fin structure and the second fin structure, respectively. The first gate structure are wrapped around the etch stop layer, the second semiconductor layer, and the middle insulator of the first fin structure. The second gate structure are wrapped around fifth semiconductor, the etch stop layer, the second semiconductor layer, and the middle insulator of the second fin structure.

In yet another exemplary aspect, the present disclosure is directed to a semiconductor structure. The semiconductor structure includes a first transistor and a second transistor stacked with the first transistor. The first transistor includes first nanostructures over a substrate, first source/drain features attached to opposite sides of the first nanostructures in a first horizontal direction, and a first portion of a first gate structure, wrapped around each of the first nanostructures. The first nanostructures are spaced apart from each other in a vertical direction. The second transistor includes a second nanostructure over the first nanostructures and a first etch stop layer over the second nanostructure, second source/drain features attached to opposite sides of the second nanostructure in the first horizontal direction, and a second portion of the first gate structure wrapped around each of the second nanostructures and the first etch stop layer. The second source/drain features are disposed over the first source/drain features. The semiconductor structure further includes a first middle insulator formed between the first nanostructures and the second nanostructures. The first gate structure are further wrapped around the first middle insulator.

In yet another exemplary aspect, the present disclosure is directed to a method of forming a semiconductor structure. The method includes forming a fin structure including a first stack, a middle insulator over the first stack, and a second stack over the middle insulator. The second stack includes first semiconductor layers and a second semiconductor layer alternately stacked, a third semiconductor layer over a topmost one of the first semiconductor layers, a fourth semiconductor layer over the third semiconductor layer, and a fifth semiconductor layer over the fourth semiconductor layer. The method further includes forming a dummy gate structure over the fin structure, forming gate spacers on opposite of the dummy gate structure, and etching the fin structure to form source/drain trenches on opposite sides of the dummy gate structure. The method further includes replacing the third semiconductor layer with an etch stop layer, removing a dummy gate electrode layer of the dummy gate structure, and forming a mask layer that exposes a dummy gate dielectric layer of the dummy gate structure and covers the gate spacers. The method further includes removing the dummy gate dielectric layer, the fifth semiconductor layer, and the fourth semiconductor layer, so as to expose the etch stop layer, removing the mask layer, removing the first semiconductor layers, and forming a first gate structure that is wrapped around the etch stop layer and the second semiconductor layer.

In some embodiments, the removing of the fifth semiconductor layer partially removes the fifth semiconductor layer, wherein the remaining portions of the fifth semiconductor layer are located under the gate spacers and between the gate spacers and the etch stop layer.

In some embodiments, the first stack includes sixth semiconductor layers and seventh semiconductor layers alternately stacked. The method further includes removing the sixth semiconductor layers, and forming a second gate structure that is wrapped around the sixth semiconductor layers. The second gate structure is under the first gate structure.

In some embodiments, the method further includes forming a first epitaxial structure and a first bonding layer on the first epitaxial structure, and forming a second epitaxial structure and a second bonding layer on the second epitaxial structure. The method further includes bonding the first epitaxial structure and the second epitaxial structure to form a third epitaxial structure by bonding the first bonding layer with the second bonding layer, and patterning the third epitaxial structure to form the fin structure.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method of forming a semiconductor structure, comprising:
forming a first epitaxial structure and a first bonding layer on the first epitaxial structure, and forming a second epitaxial structure and a second bonding layer on the second epitaxial structure;
bonding the first epitaxial structure and the second epitaxial structure to form a third epitaxial structure by bonding the first bonding layer with the second bonding layer;
patterning the third epitaxial structure to form a fin structure;
forming a dummy gate structure over the fin structure, wherein the dummy gate structure comprises a dummy gate dielectric layer and a dummy gate electrode layer on the dummy gate dielectric layer;
etching the fin structure to form source/drain trenches on opposite sides of the dummy gate structure;
forming first source/drain features and second source/drain features over the first source/drain features in the source/drain trenches;
forming a first gate trench exposing the dummy gate dielectric layer of the dummy gate structure;
performing an etching process to remove the dummy gate dielectric layer of the dummy gate structure and a topmost semiconductor layer of the fin structure through the first gate trench; and
forming a gate structure in the first gate trench.

2. The method of claim 1,
wherein the fin structure comprises a first stack, a middle insulator over the first stack, and a second stack over the middle insulator,
wherein the first stack comprises first semiconductor layers and second semiconductor layers alternately stacked, and
wherein the second stack comprises third semiconductor layers and a fourth semiconductor layer alternately stacked, a fifth semiconductor layer over a topmost one of the third semiconductor layers, a sixth semiconductor layer over the fifth semiconductor layer, and a seventh semiconductor layer over the sixth semiconductor layer.

3. The method of claim 2,
wherein the middle insulator is formed from the first bonding layer and the second bonding layer, and
wherein the topmost semiconductor layer of the fin structure is the seventh semiconductor layer.

4. The method of claim 2, further comprising:
removing the fifth semiconductor layer through the source/drain trenches to form a recess; and
depositing a dielectric material to form an etch stop layer in the recess.

5. The method of claim 4, further comprising removing the sixth semiconductor layer of the fin structure to expose the etch stop layer of the fin structure during the etching process.

6. The method of claim 2, further comprising:
removing the dummy gate dielectric layer, the first semiconductor layers, the third semiconductor layers, and the sixth semiconductor layer to extend the first gate trench, so as to expose the second semiconductor layers, the middle insulator, and the fourth semiconductor layer,
wherein the gate structure is further wrapped around the second semiconductor layers, the middle insulators, and the fourth semiconductor layer.

7. The method of claim 2, further comprising:
forming contact etch stop layers (CESLs) on the second source/drain features; and
forming interlayer dielectric (ILD) layers on the CESLs.

8. The method of claim 7, wherein the forming of the first gate trench comprises:
removing the dummy gate electrode layer of the dummy gate structure; and
forming a mask layer covering the CESLs and the ILD layers, so as to form the first gate trench exposing the dummy gate dielectric layer of the dummy gate structure.

9. A method of forming a semiconductor structure, comprising:
forming a first fin structure and a second fin structure each comprising a first stack, a middle insulator over the first stack, and a second stack over the middle insulator, wherein the second stack comprises first semiconductor layers and a second semiconductor layer alternately stacked, a third semiconductor layer over a topmost one of the first semiconductor layers, a fourth semiconductor layer over the third semiconductor layer, and a fifth semiconductor layer over the fourth semiconductor layer;
forming a first dummy gate structure and a second dummy gate structure over the first fin structure and the second fin structure, respectively;
etching the first fin structure and the second fin structure, so as to form first source/drain trenches on opposite sides of the first dummy gate structure and form second source/drain trenches on opposite sides of the second dummy gate structure;
replacing the third semiconductor layers of the first fin structure and the second fin structure with etch stop layers;
removing the first dummy gate structure and the fifth semiconductor layer and the fourth semiconductor layer of the first fin structure, so as to expose the etch stop layer of the first fin structure;
removing the fourth semiconductor layer of the second fin structure, and removing the first semiconductor layers of the first fin structure and the second fin structure; and
forming a first gate structure and a second gate structure on the first fin structure and the second fin structure, respectively,
wherein the first gate structure is wrapped around the etch stop layer, the second semiconductor layer, and the middle insulator of the first fin structure, and wherein the second gate structure is wrapped around the fifth semiconductor, the etch stop layer, the second semiconductor layer, and the middle insulator of the second fin structure.

10. The method of claim 9, wherein each of the first dummy gate structure and the second dummy gate structure comprises a dummy gate dielectric layer and a dummy gate electrode layer on the dummy gate dielectric layer, and the method further comprises:
performing a first etching process to remove the dummy gate electrode layers of the first dummy gate structure and the second dummy gate structure;
forming a mask layer that exposes the dummy gate dielectric layer of the first dummy gate structure and covers the dummy gate dielectric layer of the second dummy gate structure; and
performing a second etching process to remove the dummy gate dielectric layer of the first dummy gate structure, and remove the fifth semiconductor layer and the fourth semiconductor layer of the first fin structure,
wherein the first dummy gate structure is removed during the first etching process and the second etching process.

11. The method of claim 10, further comprising:
forming first source/drain features in the first source/drain trenches;
forming contact etch stop layers (CESLs) on the first source/drain features; and
forming interlayer dielectric (ILD) layers on the CESLs.

12. The method of claim 11, wherein the mask layer further covers the ILD layers and the CESLs.

13. The method of claim 9,
wherein the first stack comprises sixth semiconductor layers and seventh semiconductor layers alternately stacked, and
wherein the middle insulator is formed over a topmost one of the sixth semiconductor layers.

14. The method of claim 13, further comprising:
removing the sixth semiconductor layers of the first fin structure and the second fin structure, wherein the first gate structure and the second gate structure are further wrapped around the seventh semiconductor layers of the first fin structure and the second fin structure, respectively.

15. The method of claim 9, further comprising:
forming a first epitaxial structure over a first substrate, and forming a first bonding layer on the first epitaxial structure;
forming a second epitaxial structure over a second substrate, and forming a second bonding layer on the second epitaxial structure; and
bonding the first epitaxial structure and the second epitaxial structure to form a third epitaxial structure by bonding the first bonding layer with the second bonding layer.

16. The method of claim 15, further comprising:
thinning the third epitaxial structure from the second substrate, wherein the second substrate is thinned into the fifth semiconductor layer; and
patterning the third epitaxial structure to form the first fin structure and the second fin structure.

17. A semiconductor structure, comprising:
a first transistor, comprising:
first nanostructures over a substrate, wherein the first nanostructures are spaced apart from each other in a vertical direction;
first source/drain features, attached to opposite sides of the first nanostructures in a first horizontal direction; and
a first portion of a first gate structure, wrapped around each of the first nanostructures;
a second transistor stacked with the first transistor, wherein the second transistor comprises:
a second nanostructure over the first nanostructures and a first etch stop layer over the second nanostructure, wherein the second nanostructure and the first etch stop layer are spaced apart from each other in the vertical direction;
second source/drain features, attached to opposite sides of the second nanostructure in the first horizontal direction and disposed over the first source/drain features; and
a second portion of the first gate structure, wrapped around each of the second nanostructures and the first etch stop layer; and
a first middle insulator, formed between the first nanostructures and the second nanostructures, wherein the first gate structure is further wrapped around the first middle insulator.

18. The semiconductor structure of claim 17, further comprising:
a third transistor, comprising:
third nanostructures over the substrate, wherein the third nanostructures are spaced apart from each other in the vertical direction;
third source/drain features, attached to opposite sides of the third nanostructures in the first horizontal direction; and
a first portion of a second gate structure, wrapped around each of the third nanostructures;
a fourth transistor stacked with the third transistor, wherein the fourth transistor comprises:
fourth nanostructures over the third nanostructures;
a second etch stop layer between and spaced apart from a topmost one and a bottommost one of the fourth nanostructures in the vertical direction;
fourth source/drain features, attached to opposite sides of the fourth nanostructures in the first horizontal direction and disposed over the third source/drain features; and
a second portions of the second gate structure, wrapped around each of the fourth nanostructures and the second etch stop layer; and
a second middle insulator, formed between the third nanostructures and the fourth nanostructures, wherein the second gate structure is further wrapped around the second middle insulator.

19. The semiconductor structure of claim 17, further comprising:
first gate spacers, formed on opposite sides of the second portion of the first gate structure in the first horizontal direction; and
semiconductor segments, formed on the opposite sides of the second portion of the first gate structure, under the first gate spacers, and between the first gate spacers and the first etch stop layer.

20. The semiconductor structure of claim 17, further comprising:
contact etch stop layers (CESLs); and
interlayer dielectric (ILD) layers formed on the CESLs,
wherein the CESLs and the ILD layers are formed between the first source/drain features and the second source/drain features.
